(19) United States
(12) Patent Application Publication
(10) Pub. No.: US 2012/0064459 A1
(43) Pub. Date: Mar. 15, 2012

(54) Water Repellent Additive for Immersion Resist

(75) Inventors: Kazuhiko Maeda, Tokyo (JP); Takamasa Kitamoto, Saitama (JP); Haruhiko Komoriya, Saitama (JP); Satoru Narizuka, Saitama (JP); Yoshimi Isono, Saitama (JP); Kazunori Mori, Saitama (JP)

(73) Assignee: Central Glass Company, Limited, Ube-shi (JP)

(21) Appl. No.: 13/320,871

(22) PCT Filed: May 14, 2010
(86) PCT No.: PCT/JP2010/058208

§ 371 Date: Nov. 16, 2011

(30) Foreign Application Priority Data
May 25, 2009 (JP) 2009-125780

(51) Int. Cl. G03F 7/039; C08F 20/22; G03F 7/38

(52) U.S. Cl. 430/285.1; 430/326; 526/245

(57) ABSTRACT

Disclosed is a water repellent additive for an immersion resist, which is composed of a fluorine-containing polymer that has a repeating unit represented by general formula (1). By adding the water repellent additive to a resist composition, the resist composition can be controlled to have high water repellency during exposure and to exhibit improved solubility in a developing solution during development.

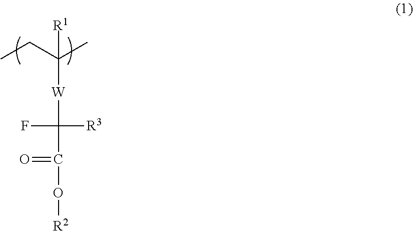

[In the formula, R¹ represents a hydrogen atom, a fluorine atom, a methyl group or a trifluoromethyl group; R² represents a heat-labile protecting group; R³ represents a fluorine atom or a fluorine-containing alkyl group; and W represents a divalent linking group.]

### TECHNICAL FIELD

The present invention relates to a water repellent additive for an immersion resist, which is composed of a fluorine-containing polymer that has a specified repeating unit. This water repellent additive is useful as a water repellent additive used particularly in topcoatless immersion exposure process.

### BACKGROUND OF THE INVENTION

Fluorine-containing compounds are developed and used in a wide application field of advanced materials, by virtue of properties owned by fluorine, such as water repellency, oil repellency, low water absorption, heat resistance, weatherability, corrosion resistance, transparency, photosensitivity, low refractive index, and low dielectric property. Particularly recently, there have been active researches on resist materials of fluorine-containing compounds as novel materials having a high transparency to short wavelength ultraviolet rays such as F₂ laser and ArF excimer laser. A common molecular design in these application fields is based on the achievement of various performances including: transparency at each wavelength used by introducing fluorine; photosensitivity utilizing acid properties of fluoroalcohol such as 1,1,1,3,3,3-hexafluoroisopropyl-2-hydroxyl group (it may be referred to as a hexafluoroisopropyl hydroxyl group); and adhesive property to a substrate.

On the other hand, together with the trend toward micro-scale device structure, there has been a demand for micro-scale resist pattern in lithography step, and therefore the improvement of an exposure apparatus has been studied.

For example, a stepper (a reduced projection type exposure apparatus) has dramatically been improved also in resolution performance by the performance improvement of reduction projector lenses and the improvement of optical designs. The performance of lenses used in the stepper is expressed by NA (numerical aperture). The physical limit of NA value in the air is said to be around 0.9, which has already been attained at the present time. Hence, it is being attempted to raise NA to 1.0 or more by filling the space confined between a lens and a wafer with a medium having a refractive index larger than that of air, in which an exposure technique that adopts an immersion method using pure water (hereinafter, which may be referred to as merely water) as the medium has received great attention (Non-Patent Publication 1).

In immersion lithography, various concerns resulted from contact between a resist film and a medium (e.g., water) have been pointed out. In particular, the pattern shape change caused by that an acid generated in the film by exposure or an amine compound added as a quencher is dissolved in water, the pattern collapse caused by swelling, and the like become problems. In view of this, there is given a report that a topcoat layer disposed on the resist is effective at separating the resist film from water (Non-Patent Publication 2).

A top coat composition is required to exhibit such performances as a good solubility in a developing solution, resistance against pure water, separability between the resist film and water, and no corrosion on the resist film disposed as underlayer. As a top coat composition satisfying the above-mentioned requirements, there has been developed a composition comprised of a fluorine-containing polymer that has a repeating unit including a unit having two or more hexafluoroisopropyl hydroxyl groups. This composition has been reported to have a particularly excellent solubility in a developing solution (Patent Publication 1). Incidentally, a hexafluoroisopropyl hydroxyl group is represented by the following structure and receives attention as a unit high in fluorine content and having a hydroxyl group (which is a polar group) in the same molecule.

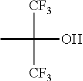

Hexafluoroisopropyl Hydroxyl Group

On the other hand, as another method for controlling elution of a resist composition and penetration of water, there has been proposed a method of adding a water repellent compound soluble in a developing solution to a resist material and then applying it to a substrate thereby causing segregation of the water repellent composition on the surface of a resist film (Patent Publication 2). Since a topcoat layer is not employed therein, this method is referred to as a topcoatless resist and excellent in the sense that steps relating to formation and removal of a topcoat film are not needed.

In order to improve water repellency, it is effective to use a resist composition containing fluorine atoms, and hence there have hitherto been developed various fluorine-containing polymers used for fluorine-containing resist. The present applicant has disclosed difluoro acetates having both a polymerizable double bond-containing group and an acid-labile protecting group (Patent Publication 3) and difluoroacetic acids having a polymerizable double bond-containing group (Patent Publication 4).

### REFERENCES ABOUT PRIOR ART

### Patent Publication

Patent Publication 1: Japanese Patent Application Publication No. 2005-316352

Patent Publication 2: Japanese Patent Application Publication No. 2006-48029

Patent Publication 3: Japanese Patent Application Publication No. 2009-19199

Patent Publication 4: Japanese Patent Application Publication No. 2009-29802

### Non-Patent Publication

Non-Patent Publication 1: Proceedings of SPIE (((Issuing Country) the U.S.A.) 2002, vol. 4691, pp. 459-465)

Non-Patent Publication 2: 2nd Immersion Work Shop, Jul. 11, 2003, Resist and Cover Material Investigation for Immersion Lithography

### SUMMARY OF THE INVENTION

In order to solve the above-mentioned problems of immersion lithography, a topcoat method and a topcoatless method using a water repellent additive are effective. However, a solvent capable of dissolving a photoresist cannot be employed as one used for a solution for topcoat application. Furthermore, an increase of the number of steps relating to formation and removal of a topcoat layer increases the cost of manufacturing, and additionally an exposure performance is affected by application or removal of topcoat. Meanwhile, among topcoatless methods, the method of Patent Publication 2 carries a problem on wettability between an alkali developing solution and a resist surface due to segregation of a water repellent additive caused on the surface, and therefore tends to cause defect. Hence there has been demanded the development of a water repellent additive which is so controllable as to exhibit improved solubility in a developing solution during development while keeping its water barrier properties during exposure.

The present invention was achieved in view of the above circumstances, the challenge of which is to provide a water repellent additive which is usable in topcoatless method of immersion lithography and controllable to have a high water repellency during exposure and to exhibit an improved solubility in a developing solution during development.

As a result of studying the introduction of fluorine atom into a resin in order to improve water repellency of the additive for an immersion resist, the present inventors found that the introduction of fluorine atom into α-position of carbonyl group of ester group makes it possible to greatly improve water repellency and to obtain a high receding contact angle. More surprisingly, we found that the introduction of the structure into a resin makes it possible to easily release the protecting group of carboxylic acid by heat treatment so that the solubility in a developing solution is significantly enhanced by the heat treatment as a turning point thereby allowing controlling a developing solution-solubility by heat, which leads the present invention to attainment.

In other words, a water repellent additive for an immersion resist, which is characterized by comprising a fluorine-containing polymer that has a repeating unit represented by general formula (1), is useful as a water repellent additive for immersion topcoatless resist process. The water repellent additive causes segregation on the surface of a resist film thereby exhibiting a high water repellency, with which it becomes possible to perform a high-speed scanning by an immersion exposure apparatus to improve productivity. Furthermore, defects of resist pattern can be reduced because the contact angle at the surface at which carboxylic acid becomes exposed together with releases of protecting groups due to heat treatment is decreased and the dissolution into the developing solution proceeds rapidly.

The present invention thus makes it possible to introduce an excellently water-repellent component into a resinous component and to control a developing solution-solubility by heat treatment. With this, both “high water repellency during exposure” and “improvement of the developing solution-solubility during development” are accomplished, which has hitherto been difficult. Thus it is allowed to get a topcoat unnecessary in immersion lithography.

The present invention involves the following Invention 1 to Invention 9.

[Invention 1]

A water repellent additive for an immersion resist, used by being added to a resist composition, comprising a fluorine-containing polymer that has a repeating unit represented by the following general formula (1).

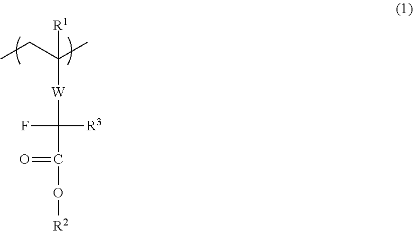

[In the formula: R¹ represents a hydrogen atom, a fluorine atom, a methyl group or a trifluoromethyl group; R² represents a heat-labile protecting group; R³ represents a fluorine atom or a fluorine-containing alkyl group; and W represents a divalent linking group.]

[Invention 2]

A water repellent additive of Invention 1, characterized in that the fluorine-containing polymer is a fluorine-containing polymer in which R³ represents a fluorine atom or a fluorine-containing alkyl group having a carbon number of 1-3.

[Invention 3]

A water repellent additive of Invention 1 or 2, characterized in that the fluorine-containing polymer is a fluorine-containing polymer that has a repeating unit represented by any one of the following general formulas (1-1) to (1-4).

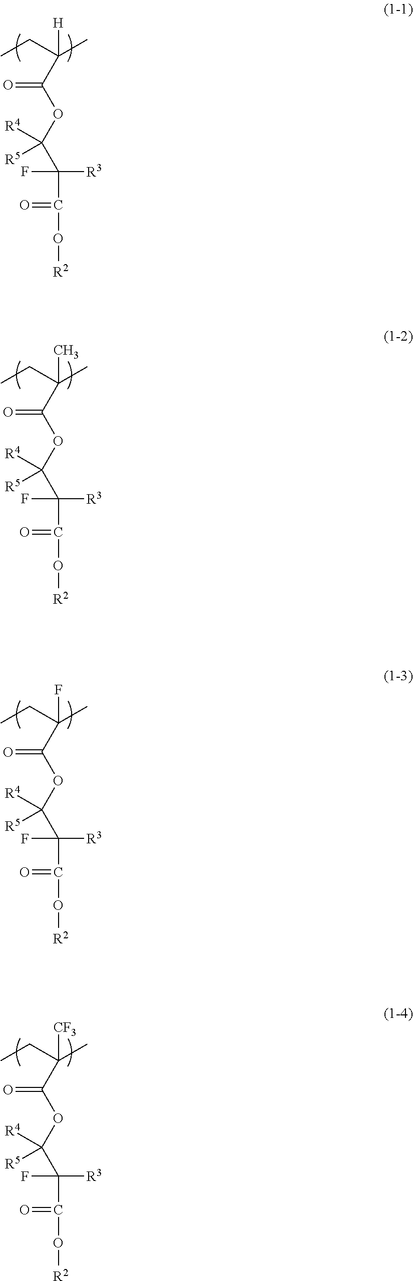

[In the formula: R² represents a heat-labile protecting group; R³ represents a fluorine atom or a trifluoromethyl group; R⁴ represents a hydrogen atom or a linear, branched or cyclic alkyl group or fluoroalkyl group; R⁵ represents a linear, branched or cyclic alkyl group or fluoroalkyl group; and R⁴ and R⁵ may be bonded to each other to form a ring.]

[Invention 4]

A water repellent additive of Invention 3, wherein the fluorine-containing polymer is a fluorine-containing polymer in which R² is 1-methylcyclopentyl group or 1-ethylcyclopentyl group, R³ is a fluorine atom, R⁴ is a hydrogen atom, and R⁵ is a lower alkyl group.

[Invention 5]

A water repellent additive of any one of Inventions 1 to 4, wherein the fluorine-containing polymer is a fluorine-containing polymer that has a repeating unit obtained by a cleavage of a polymerizable monomer having a hexafluoroisopropyl hydroxyl group.

[Invention 6]

A water repellent additive-containing resist composition comprising:

a resist composition comprising:
(A) a polymer that becomes soluble in an alkali developing solution by an action of acid,
(B) a photoacid generator,
(C) a basic compound, and
(D) a solvent; and

a water repellent additive of any one of Inventions 1 to 5 which additive is added to the resist composition.

[Invention 7]

A pattern forming method characterized by comprising:

(1) a step of applying a water repellent additive-containing resist composition of Invention 6 on a substrate;

(2) a step of conducting an exposure with a high-energy ray having a wavelength of 300 nm or shorter through a photomask under a condition that a medium is inserted between a projector lens and the substrate, after subjecting the coated substrate to a prebaking; and

(3) a step of carrying out a post-exposure baking of the substrate which had been subjected to the exposure, and then conducting a development by using a developing solution.

[Invention 8]

A pattern forming method of Invention 7, characterized in that the post exposure bake treatment before the development is conducted at 60° C. to 170° C.

[Invention 9]

A pattern forming method of Invention 7 or 8, characterized by using a high-energy ray having a wavelength within a range of from 180 to 300 nm, as an exposure light source.

### DETAILED DESCRIPTION

A water repellent additive for photoresist, according to the present invention allows a resist film to exhibit a high water repellency, by being added to a resist composition. With this, it becomes possible to perform a high-speed scanning by an immersion exposure apparatus to improve productivity. Furthermore, it is possible to significantly enhance the solubility in a developing solution by conducting the development after heat treatment thereby reducing defects of resist pattern.

In a fluorine-containing polymer represented by general formula (1) of the present invention, a chain skeleton formed on the basis of a polymerizable double bond, and a carboxyl group wherein one fluorine atom and a fluorine atom or fluorine-containing alkyl group are bonded to a carbon atom of α-position and wherein a heat-labile protecting group R² forms an ester bond are bonded through a linking group W.

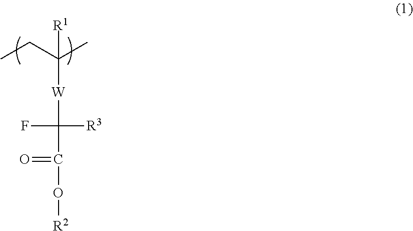

<Fluorine-Containing Polymer>

The fluorine-containing polymer having a repeating unit represented by general formula (1) is a resin of which rate of dissolution in an alkali developing solution increases by an action of heat or acid, and has a group (decomposable group) that decomposes by an action of heat or acid to become alkali-soluble. Although the decomposable group of the fluorine-containing polymer of the present invention decomposes by either heat or acid, it is referred to as a heat-decomposable group since a control by heat treatment is basic in the present specification. In the heat-decomposable group, a leaving moiety is referred to as a heat-labile protecting group.

Since a moiety to which the above heat-decomposable group is bonded is also capable of decomposing by an action of acid, it is also possible to use a photoacid generator or heat acid generator used in the common resist development. Under an action of acid generator, a heat-decomposable group or thermal decomposition-stable protecting group referred to in the present specification can be read as an acid-decomposable group or acid decomposition-stable protecting group.

R¹ is a hydrogen atom, fluorine atom, methyl group or trifluoromethyl group. R³ is a fluorine atom or fluorine-containing alkyl group. Such fluorine-containing alkyl group is not particularly limited, but it is one having a carbon number of 1-12, preferably one having a carbon number of 1-3. It is possible to mention trifluoromethyl group, pentafluoroethyl group, 2,2,2-trifluoroethyl group, n-heptafluoropropyl group, 2,2,3,3,3-pentafluoropropyl group, 3,3,3-trifluoropropyl group, hexafluoroisopropyl group, etc. R³ is more preferably a fluorine atom or trifluoromethyl group.

As a heat-labile protecting group represented by R², it is possible to cite the followings.

R¹¹—O—C(═O)— (L-1)

R¹¹—O—CHR¹²— (L-2)

CR¹³R¹⁴R¹⁵— (L-3)

SiR¹³R¹⁴R¹⁵— (L-4)

R¹¹—C(═O)— (L-5)

R¹¹, R¹², R¹³, R¹⁴ and R¹⁵ represent monovalent organic groups explained in the following. Of these, (L-1), (L-2) and (L-3) function as a chemically amplified type and therefore are particularly preferable to be used as a resist composition applied to a pattern forming method in which exposure is conducted with a high-energy ray.

R¹¹ represents an alkyl group, alicyclic hydrocarbon group, or aryl group (aromatic hydrocarbon group). R¹² represents a hydrogen atom, alkyl group, alicyclic hydrocarbon group, alkenyl group, aralkyl group, alkoxy group, or aryl group. R¹³, R¹⁴ and R¹⁵ may be the same or different and represent alkyl groups, alicyclic hydrocarbon groups, alkenyl groups, aralkyl groups, or aryl groups. Furthermore, two groups of R¹³ to R¹⁵ may be combined to form a ring.

Herein, the alkyl group is preferably one having a carbon number of 1-4, such as methyl group, ethyl group, propyl group, isopropyl group, n-butyl group, sec-butyl group, and tert-butyl group. As the alicyclic hydrocarbon group, it is possible to cite one having a carbon number of 3-30. Specifically, it is preferably one having a carbon number of 3-30, such as cyclopropyl group, cyclopentyl group, cyclohexyl group, adamantyl group, norbornyl group, bornyl group, tricyclodecanyl group, dicyclopentenyl group, norbornaneepoxy group, menthyl group, isomenthyl group, neomenthyl group, tetracyclododecanyl group, and steroid residue. The alkenyl group is preferably one having a carbon number of 2-4, such as vinyl group, propenyl group, allyl group, and butenyl group. The aryl group is preferably one having a carbon number of 6-14, such as phenyl group, xylyl group, tolyl group, cumenyl group, naphthyl group, and antracenyl group, and these may have substituents. As the aralkyl group, it is possible to cite one having a carbon number of 7-20, optionally having a substituent. It is possible to cite benzyl group, phenethyl group, cumyl group, etc.

Furthermore, as the substituents further possessed by the organic groups, it is possible to cite hydroxyl group, halogen atoms, nitro group, cyano group, the above alkyl groups or alicyclic hydrocarbon groups, alkoxy groups such as methoxy group, ethoxy group, hydroxyethoxy group, propoxy group, hydroxypropoxy group, n-butoxy group, isobutoxy group, sec-butoxy group and tert-butoxy group, alkoxycarbonyl groups such as methoxycarbonyl group and ethoxycarbonyl group, aralkyl groups such as benzyl group, phenethyl group and cumyl group, acyl groups such as aralkyloxy group, formyl group, acetyl group, butyryl group, benzoyl group, cyanamyl group and valeryl group, acyloxy groups such as butyloxy group, the above alkenyl groups, alkenyloxy groups such as vinyloxy group, propenyloxy group, allyloxy group and butenyloxy group, the above aryl groups, aryloxy groups such as phenoxy group, and aryloxycarbonyl groups such as benzoyloxy group.

Furthermore, it is possible to cite lactone groups represented by the following formula (3-1) and formula (3-2).

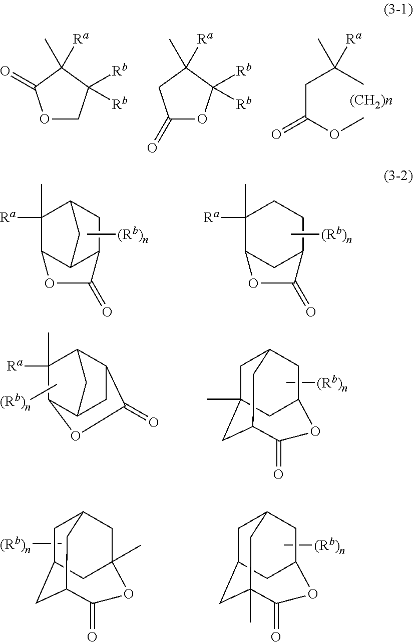

In the above formulas, R^{a} represents a C₁-C₄ alkyl group or perfluoroalkyl group. Each of R^{b}'s independently represents a hydrogen atom, C₁-C₄ alkyl group or perfluoroalkyl group, hydroxyl group, carboxylic acid group, alkyloxycarbonyl group, alkoxy group, etc., and n represents an integer of 1-4.

Then, the above heat-labile protecting group is specifically shown. These are particularly preferable examples. Of these, examples exemplarily shown as tertiary hydrocarbon groups represented by CR¹³R¹⁴R¹⁵— are more preferable.

The alkoxycarbonyl group represented by the above R¹¹—O—C(═O)— can be exemplified by tert-butoxycarbonyl group, tert-amyloxycarbonyl group, methoxycarbonyl group, ethoxycarbonyl group, i-propoxycarbonyl group, cyclohexyloxycarbonyl group, isobornyloxycarbonyl group, adamantaneoxycarbonyl group, etc.

As the acetal group represented by the above R¹¹—O—CHR¹²—, it is possible to cite methoxymethyl group, ethoxymethyl group, 1-ethoxyethyl group, 1-butoxyethyl group, 1-isobutoxyethyl group, 1-cyclohexyloxyethyl group, 1-benzyloxyethyl group, 1-phenethyloxyethyl group, 1-ethoxypropyl group, 1-benzyloxypropyl group, 1-phenethyloxypropyl group, 1-ethoxybutyl group, 1-cyclohexyloxyethyl group, 1-ethoxyisobutyl group, 1-methoxyethoxymethyl group, tetrahydropyranyl group, tetrahydrofuranyl group, etc. Furthermore, it is possible to cite acetal groups obtained by adding vinyl ethers to hydroxyl group.

The tertiary hydrocarbon group represented by the above CR¹³R¹⁴R¹⁵— can be exemplified by tert-butyl group, tert-amyl group, 1,1-dimethylpropyl group, 1-ethyl-1-methylpropyl group, 1,1-dimethylbutyl group, 1-ethyl-1-methylbutyl group, 1,1-diethylpropyl group, 1,1-dimethyl-1-phenylmethyl group, 1-methyl-1-ethyl-1-phenylmethyl group, 1,1-diethyl-1-phenylmethyl group, 1-methylcyclohexyl group, 1-ethylcyclohexyl group, 1-methylcyclopentyl group, 1-ethylcyclopentyl group, 1-isobornyl group, 1-methyladamantyl group, 1-ethyladamantyl group, 1-isopropyladamantyl group, 1-isopropylnorbornyl group, and 1-isopropyl-(4′-methylcyclohexyl) group, etc.

Then, specific examples of the alicyclic hydrocarbon group or the heat-labile protecting group containing an alicyclic hydrocarbon group are further shown.

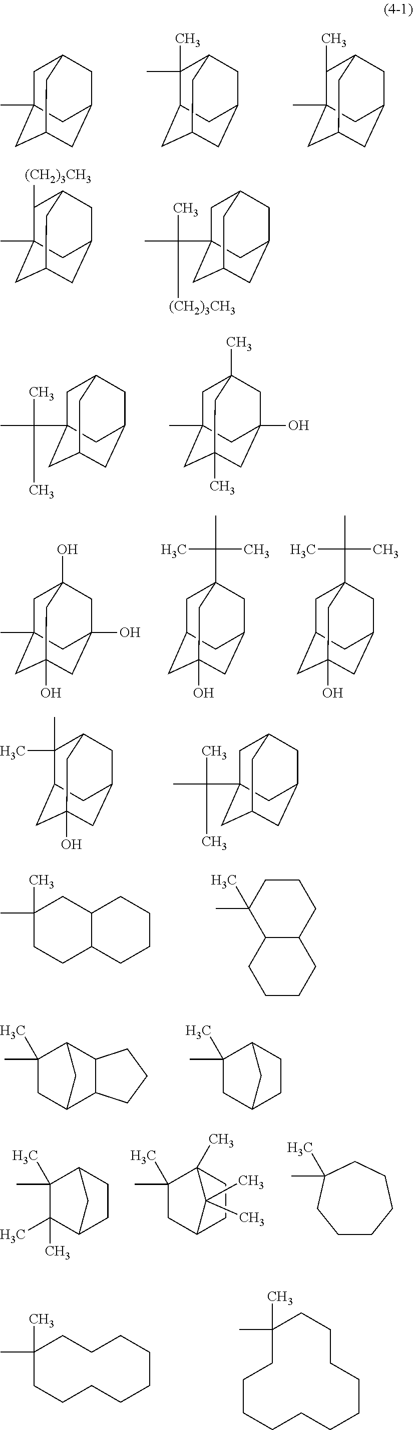

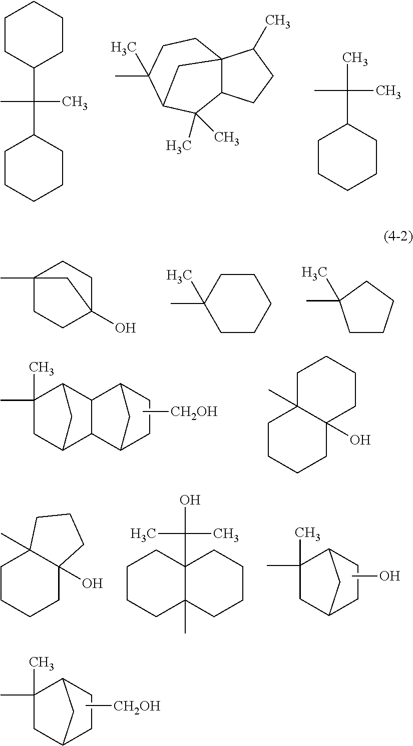

In the formulas of (4-1) and (4-2), each methyl group (CH₃) may independently be an ethyl group. Furthermore, one or at least two of ring carbons can have a substituent, as mentioned above.

As the silyl group represented by the above SiR¹³R¹⁴R¹⁵—, it is possible to cite, for example, trimethylsilyl group, ethyldimethylsilyl group, methyldiethylsilyl group, triethylsilyl group, i-propyldimethylsilyl group, methyldi-i-propylsilyl group, tri-i-propylsilyl group, tert-butyldimethylsilyl group, methyldi-tert-butylsilyl group, tri-tert-butylsilyl group, phenyldimethylsilyl group, methyldiphenylsilyl group, triphenylsilyl group, etc.

As the acyl group represented by the above R¹¹—C(═O)—, it is possible to cite acetyl group, propionyl group, butyryl group, heptanoyl group, hexanoyl group, valeryl group, pivaloyl group, isovaleryl group, lauryloyl group, myristoyl group, palmitoyl group, stearoyl group, oxalyl group, malonyl group, succinyl group, glutaryl group, adipoyl group, piperoyl group, suberoyl group, azelaoyl group, sebacoyl group, acryloyl group, propioloyl group, methacryloyl group, crotonoyl group, oleoyl group, maleoyl group, fumaroyl group, mesaconoyl group, campholoyl group, benzoyl group, phthaloyl group, isophthaloyl group, terephthaloyl group, naphthoyl group, toluoyl group, hydroatropoyl group, atropoyl group, cinnamoyl group, furoyl group, thenoyl group, nicotinoyl group, isonicotinoyl group, etc. Furthermore, it is also possible to use ones in which fluorine atoms have been substituted for a part or entirety of hydrogen atoms of these heat-labile protecting groups.

Moreover, the heat-labile protecting group containing a lactone group is exemplified by the following formula (5), formula (6) and formula (7).

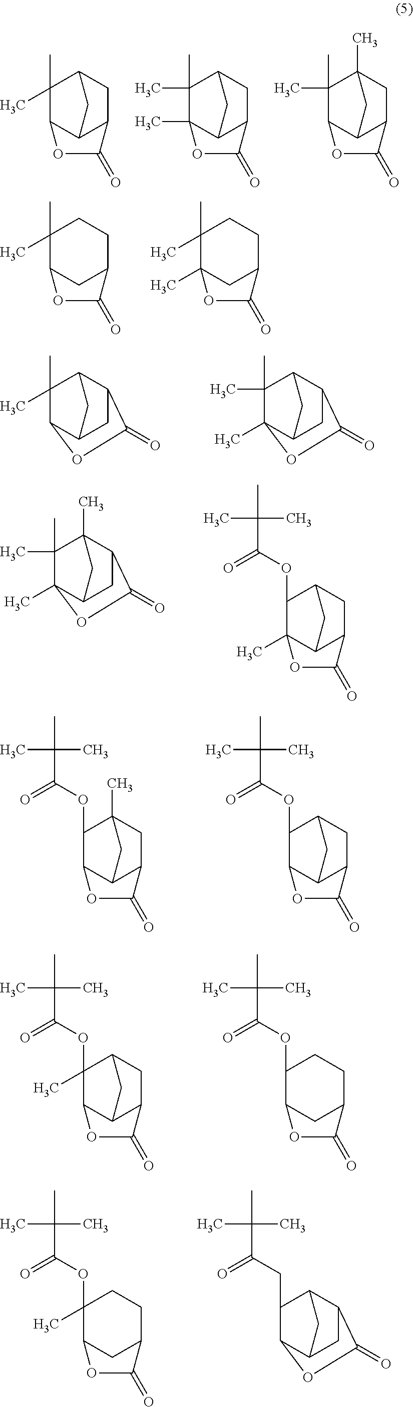

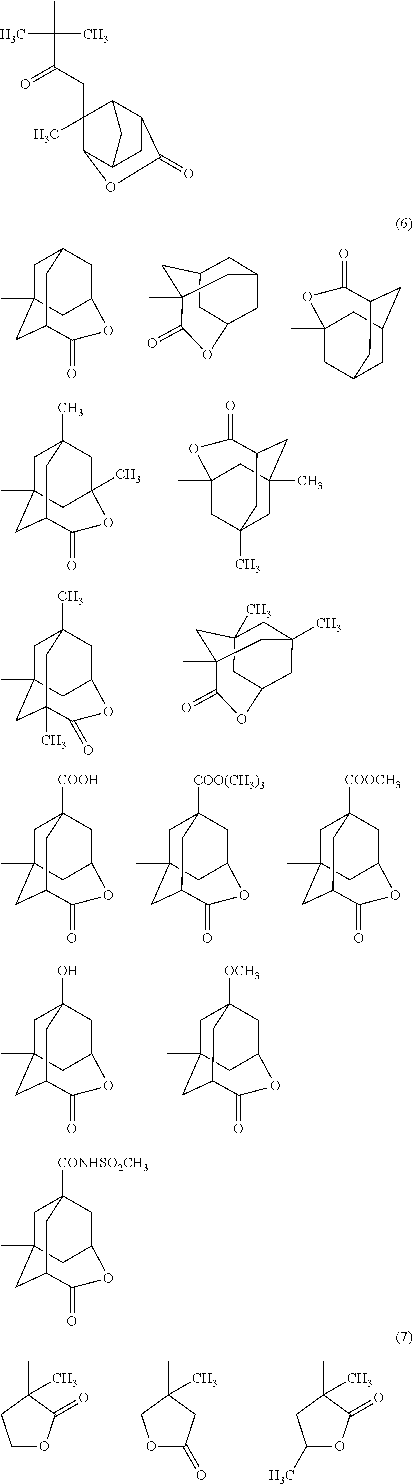

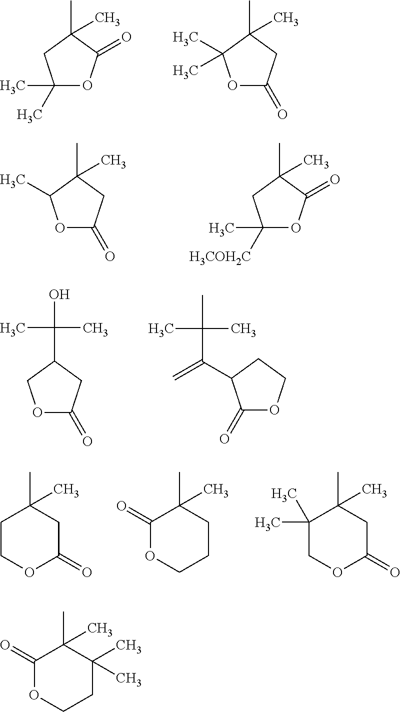

In the formulas of formula (5), formula (6) and formula (7), each methyl group (CH₃) may independently be an ethyl group.

As the heat-labile protecting group in the case of using an ArF excimer laser as an exposure light source, it is possible to cite as preferable ones tertiary alkyl groups such as tert-butyl group and tert-amyl group, alkoxyethyl groups such as 1-ethoxyethyl group, 1-butoxyethyl group, 1-isobutoxyethyl group and 1-cyclohexyloxyethyl group, and alkoxymethyl groups such as methoxymethyl group and ethoxymethyl group, and the above-mentioned alicyclic hydrocarbon groups such as adamantyl group and isobornyl group, or heat-labile protecting groups having a tertiary carbon containing an alicyclic hydrocarbon group, lactones, etc.

The linking group W is a divalent linking group having a main skeleton formed of a single or a combination of at least two organic groups selected from the group consisting of a single bond, an unsubstituted or substituted methylene group, a divalent cyclic alkyl group (alicyclic hydrocarbon group), a divalent aryl group (aromatic hydrocarbon group), a substituted or unsubstituted condensed polycyclic aromatic group, a divalent heterocyclic group, ether group, carbonyl group, ester group, oxocarbonyl group, thioether group, amide group, sulfonamide group, urethane group and urea group. The linking group W may contain a plurality of the same group of the above. Arbitrary number of hydrogen atoms bonded to the carbon atoms may be replaced with fluorine atoms. In the linking group, each carbon atom may form a ring by including a substituent.

A substituted methylene group constituting a main skeleton of the linking group W is represented by the following general formula (2).

—CR⁴R⁵— (2)

Herein, a monovalent group represented by R⁴ or R⁵ of the substituted methylene group is not particularly limited, but it is a hydrogen atom, halogen atom, hydroxyl group, or a monovalent organic group having a carbon number of 1 to 30 and selected from substituted or unsubstituted alkyl groups, substituted or unsubstituted alicyclic hydrocarbon groups, alkoxyl groups, substituted or unsubstituted aryl groups, and substituted or unsubstituted condensed polycyclic aromatic groups. These monovalent groups can have fluorine atom, oxygen atom, sulfur atom, nitrogen atom, or carbon-carbon double bond. R⁴ and R⁵ may be the same or different. R⁴ and R⁵ may be combined together with atoms in the molecule to form a ring. This ring preferably has an alicyclic hydrocarbon structure. As a monovalent organic group represented by R⁴ or R⁵, the following ones are cited.

As an acyclic alkyl group in R⁴ and R⁵, it is one having a carbon number of 1-30, preferably one having a carbon number of 1-12. It is possible to cite, for example, methyl group, ethyl group, n-propyl group, i-propyl group, n-butyl group, 1-methylpropyl group, 2-methylpropyl group, tert-butyl group, n-pentyl group, i-pentyl group, 1,1-dimethylpropyl group, 1-methylbutyl group, 1,1-dimethylbutyl group, n-hexyl group, n-heptyl group, i-hexyl group, n-octyl group, i-octyl group, 2-ethylhexyl group, n-nonyl group, n-decyl group, n-undecyl group, n-dodecyl group, etc. Lower alkyl groups are preferable. As particularly preferable ones, it is possible to cite methyl group, ethyl group, n-propyl group, i-propyl group, etc.

As an acyclic substituted alkyl group in R⁴ and R⁵, it is possible to cite ones in which one or at least two of hydrogen atoms possessed by the alkyl group have been replaced with a C₃-C₂₀ alicyclic hydrocarbon group, a C₁-C₄ alkoxy group, halogen atom, acyl group, acyloxy group, cyano group, hydroxyl group, carboxyl group, alkoxycarbonyl group, nitro group, or the like. An alkyl group having an alicyclic hydrocarbon group as the substituent can be exemplified by substituted alkyl groups such as cyclobutylmethyl group, cyclopentylmethyl group, cyclohexylmethyl group, cycloheptylmethyl group, cyclooctylmethyl group, norbornylmethyl group and adamantylmethyl group, and substituted alkyl groups in which hydrogen atom of these cyclic carbons has been replaced with methyl group, ethyl group or hydroxyl group. Specifically, it is possible to preferably cite lower fluoroalkyl groups such as trifluoromethyl group, pentafluoroethyl group, 2,2,2-trifluoroethyl group, n-heptafluoropropyl group, 2,2,3,3,3-pentafluoropropyl group, 3,3,3-trifluoropropyl group and hexafluoroisopropyl group, as a fluoroalkyl group having fluorine atoms substituted therefor.

Alicyclic hydrocarbon groups in R⁴ and R⁵ or alicyclic hydrocarbon groups formed by including carbon atoms to which they are bonded may be monocyclic or polycyclic. Specifically, it is possible to cite groups having monocyclo, bicyclo, tricyclo, tetracyclo structures, etc. of a carbon number of at least 3. The carbon number is preferably 3-30, and particularly preferably 3-25. These alicyclic hydrocarbon groups may have substituents.

The monocyclic group is preferably one having a ring carbon number of 3-12, more preferably one having a ring carbon number of 3-7. For example, it is possible to cite as preferable ones cyclopropyl group, cyclobutyl group, cyclopentyl group, cyclohexyl group, cycloheptyl group, cyclooctyl group, cyclodecanyl group, cyclododecanyl group, and 4-tert-butylcyclohexyl group. Furthermore, it is possible to cite as the polycyclic group adamantyl group, noradamantyl group, decaline residue, tricyclodecanyl group, tetracyclododecanyl group, norbornyl group, cedrol group, etc. of a ring carbon number of 7-15. The alicyclic hydrocarbon group may be a Spiro ring, preferably a Spiro ring of a carbon number of 3-6. Preferably, they are adamantyl group, decaline residue, norbornyl group, cedrol group, cyclohexyl group, cycloheptyl group, cyclooctyl group, cyclodecanyl group, cyclododecanyl group, tricyclodecanyl group, etc. It is possible to cite monocyclic groups in which one or at least two hydrogen atoms of the ring carbons or linking group of these organic groups have respectively independently been replaced with the above C₁₋₃₀ alkyl or substituted alkyl group, hydroxyl group, alkoxyl group, carboxyl group, alkoxycarbonyl group, or a group in which one or at least two hydrogen atoms contained in those have been replaced with fluorine atom or trifluoromethyl group.

Herein, the C₁₋₃₀ alkyl group is preferably a lower alkyl group, more preferably an alkyl group selected from the group consisting of methyl group, ethyl group, propyl group, and isopropyl group. Furthermore, as the substituent of the substituted alkyl group, it is possible to cite hydroxyl group, halogen atom or alkoxyl group. As the alkoxyl group, it is possible to cite one having a carbon number of 1-4, such as methoxy group, ethoxy group, propoxy group, butoxy group, etc. As the alkoxycarbonyl group, it is possible to cite methoxycarbonyl group, ethoxycarbonyl group, and isopropoxycarbonyl group.

As the alkoxyl group in R⁴ and R⁵, it is possible to cite one having a carbon number of 1-4, such as methoxy group, ethoxy group, propoxy group, butoxy group, etc.

The substituted or unsubstituted aryl group in R⁴ and R⁵ is one having a carbon number of 1-30. As a monocyclic group, one having a ring carbon number of 3-12 is preferable, and one having a ring carbon number of 3-6 is more preferable. It is possible to cite, for example, phenyl group, biphenyl group, terphenyl group, o-tolyl group, m-tolyl group, p-tolyl group, p-hydroxyphenyl group, p-methoxyphenyl group, mesityl group, o-cumenyl group, 2,3-xylyl group, 2,4-xylyl group, 2,5-xylyl group, 2,6-xylyl group, 3,4-xylyl group, 3,5-xylyl group, o-fluorophenyl group, m-fluorophenyl group, p-fluorophenyl group, o-trifluoromethylphenyl group, m-trifluoromethylphenyl group, p-trifluoromethylphenyl group, 2,3-bistrifluoromethylphenyl group, 2,4-bistrifluoromethylphenyl group, 2,5-bistrifluoromethylphenyl group, 2,6-bistrifluoromethylphenyl group, 3,4-bistrifluoromethylphenyl group, 3,5-bistrifluoromethylphenyl group, p-chlorophenyl group, p-bromophenyl group, p-iodophenyl group, etc.

As the substituted or unsubstituted C₁₋₃₀ condensed polycyclic aromatic group, it is possible to cite monovalent organic groups obtained by removing one hydrogen atom from pentalene, indene, naphthalene, azlene, heptalene, biphenylene, indacene, acenaphthylene, fluorene, phenarene, phenanthrene, anthracene, fluoranthene, acephenanthrylene, aceanthrylene, triphenylene, pyrene, chrysene, naphthacene, picene, perylene, pentaphene, pentacene, tetraphenylene, hexaphene, hexacene, rubicene, coronene, trinaphthylene, heptaphene, heptacene, pyranthrene, ovalene, etc. As preferable ones, it is possible to cite ones in which one or at least two hydrogen atoms of these have been replaced with fluorine atoms or C₁₋₄ alkyl groups or fluorine-containing alkyl groups.

As the monocyclic or polycyclic heterocyclic group having a ring atom number of 3-25, it is possible to cite, for example, pyridyl group, furyl group, thienyl group, pyranyl group, pyrrolyl group, thiantrenyl group, pyrazolyl group, isothiazolyl group, isoxazolyl group, pyrazinyl group, pyrimidinyl group, pyridadinyl group, tetrahydropyranyl group, tetrahydrofuranyl group, tetrahydrothiopyranyl group, tetrahydrothiofuranyl group, 3-tetrahydrothiophen-1,1-dioxide group, etc., and heterocyclic groups in which one or at least two hydrogen atoms constituting these rings have been replaced with alkyl groups, alicyclic hydrocarbon groups, aryl groups or heterocyclic groups. Furthermore, ones having a monocyclic or polycyclic ether ring or lactone ring are preferable, and are exemplified by the following.

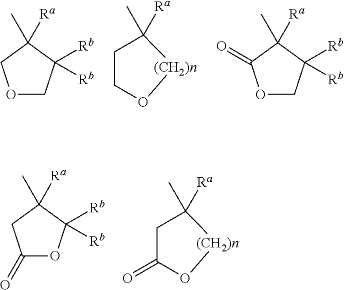

In the formula, each of R^{a} and R^{b} independently represents a hydrogen atom or C₁₋₄ alkyl group, and n represents an integer of 2-4.

The divalent alicyclic hydrocarbon group constituting a main skeleton of the linking group W may be monocyclic or polycyclic. Specifically, it is possible to cite a group having a monocyclo, bicyclo, tricyclo, tetracyclo structure, etc. having a carbon number of at least 3. The carbon number is preferably 3-30, and a carbon number of 3-25 is particularly preferable. These alicyclic hydrocarbon groups may have substituents.

The monocyclic group is preferably one having a ring carbon number of 3-12, and one having a ring carbon number of 3-7 is more preferable. For example, as preferable ones, it is possible to cite cyclopropylene group, cyclobutylene group, cyclopentylene group, cyclohexylene group, cycloheptylene group, cyclooctylene group, cyclodecanylene group, cyclododecanylene group, and 4-tert-butylcyclohexylene group. Furthermore, as the polycyclic group, it is possible to cite adamantylene group, noradamantylene group, a divalent residue of decalin, tricyclodecanylene group, tetracyclododecanylene group, norbornylene group, and a divalent residue of cedrol, having a ring carbon number of 7-15. The alicyclic hydrocarbon group may be a spiro ring, and on that occasion a spiro ring having a carbon number of 3-6 is preferable. Furthermore, it is possible to cite ones in which one or at least two of hydrogen atoms of the ring carbons or linking groups of these organic groups are independently be replaced, as explained about R⁴ or R⁵, with a C₁₋₃₀ alkyl group or substituted alkyl group, hydroxyl group, alkoxyl group, carboxyl group, alkoxycarbonyl group, or one in which one or at least two hydrogen atoms of those have been replaced with fluorine atom or trifluoromethyl group.

Herein, the C₁₋₃₀ alkyl group is preferably a lower alkyl group, more preferably an alkyl group selected from the group consisting of methyl group, ethyl group, propyl group, and isopropyl group. As a substituent of the substituted alkyl group, it is possible to cite hydroxyl group, halogen atom and alkoxyl group. As the alkoxyl group, it is possible to cite one having a carbon number of 1-4, such as methoxy group, ethoxy group, propoxy group, butoxy group, etc. As the alkoxycarbonyl group, it is possible to cite methoxycarbonyl group, ethoxycarbonyl group, and isopropoxycarbonyl group.

Specifically, the linking group W is:

-(a single bond)

—O—

—C(═O)—O—

—CH₂—O—

—O—CH₂—

—CH₂—C(═O)—O—

—C(═O)—O—CH₂—

—CH₂—O—CH₂—

—CH₂—C(═O)—O—CH₂—, etc., and

—C(═O)—O—CR⁴R⁵—, or —C₆H₄—O—CR⁴R⁵—. Herein, one in which each of R⁴ and R⁶ is independently a hydrogen atom, fluorine atom, alkyl group, substituted alkyl group, or alicyclic hydrocarbon group is preferable. These may be ones in which at least one hydrogen atom has been replaced with fluorine atom. Of these, it is possible to cite as a more preferable one —C(═O)—O—CR⁴R⁵— where each of R⁴ and R⁵ is independently a hydrogen atom or a lower alkyl group.

By showing the most preferable examples of a repeating unit represented by general formula (1), a fluorine-containing polymer having this repeating unit is shown, but this does not limit the present invention.

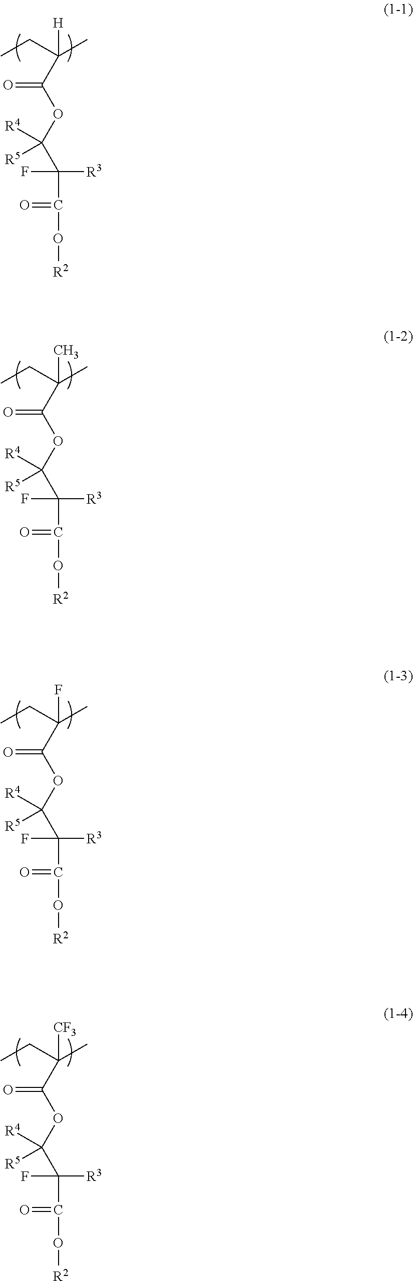

(In the formula, R² represents a heat-labile protecting group, R³ represents a fluorine atom or trifluoromethyl group, R⁴ represents a hydrogen atom, or a linear, branched or cyclic alkyl group or fluoroalkyl group, R⁵ represents a linear, branched or cyclic alkyl group or fluoroalkyl group, and R⁴ and R⁵ may be bonded to each other to form a ring.)

Herein, R² is preferably a heat-labile protecting group shown in the specific examples, or of those a tertiary hydrocarbon group represented by CR¹³R¹⁴R¹⁵—. It is particularly preferable that R³ is a fluorine atom. Furthermore, it is preferable that the alkyl group or fluorine-containing alkyl group of R⁴ and R⁵ is a lower alkyl group or fluorine-containing lower alkyl group. It is preferable that the alkyl group is a cyclic alkyl group. Furthermore, it is preferable that R⁴ is a hydrogen atom. As a particularly preferable one, it is possible to cite one in which R² is 1-methylcyclopentyl group or 1-ethylcyclopentyl group, R³ is a fluorine atom, R⁴ is a hydrogen atom or lower alkyl group, R⁵ is a lower alkyl group, or R⁴ or R⁵ is an alicyclic hydrocarbon group formed by bonding each other.

<Fluorine-Containing Monomer>

A repeating unit represented by general formula (1) and constituting a fluorine-containing polymer is formed by the production of a divalent group through cleavage of a polymerizable double bond possessed by a corresponding fluorine-containing monomer. Therefore, the explanations conducted on: the polymerizable double bond from which a chain-like skeleton moiety is derived; a group containing it each organic group; a linking group W; a heat-labile protecting group; etc. in <Fluorine-containing Polymer> can each be applied to those of the fluorine-containing monomer.

The process for producing the monomer is not particularly limited. For example, it can be produced by using a process shown in the following reaction formula [1] to reaction formula [4] (see Japanese Patent Application Publication 2009-19199).

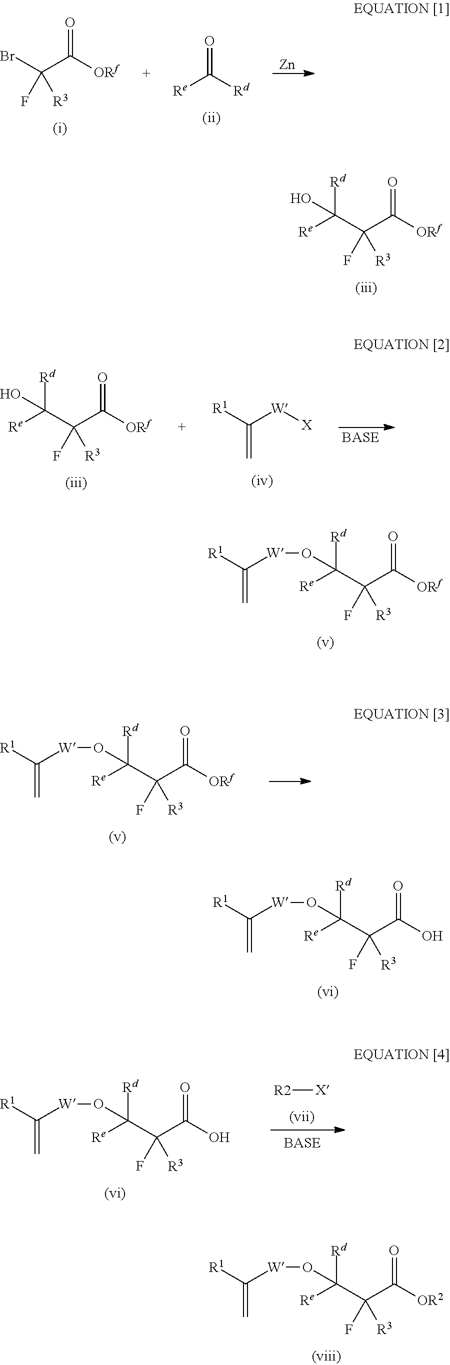

In the formulas, R¹, R² and R³ have the same meanings of R¹, R² and R³ in general formula (1). Each of R^{d}, R^{e} and R^{f} independently represents a monovalent organic group. R^{d} may, however, be a hydrogen atom. R^{d} or R^{e} corresponds to R⁴ or R⁵. Specific explanations thereof are as mentioned above, but a lower alkyl group is preferable as a monovalent organic group. Specifically, there are more preferable methyl group, ethyl group, propyl group, butyl group, cyclopentyl group, cyclohexyl group, norbornyl group, adamantyl group, trifluoromethyl group, 2,2,2-trifluoroethyl group, 1-(trifluoromethyl)ethyl group, and 3,3,3-trifluoropropyl group, or a cyclopentyl group, cyclohexyl group, or cycloheptyl group, which is formed by bonding R⁴ or R⁵ together.

Each of X and X′ independently represents a halogen atom, trifluoromethanesulfonate group, C₁₋₄ alkylsulfonate group or arylsulfonate group. W′ represents a divalent linking group. W′—O—CR^{d}R^{e} corresponds to one mode of W in general formula (1).

More specifically, a halogen-containing carboxylic acid ester (i) having an active halogen atom at α-position is reacted with a carbonyl compound (ii) in the presence of zinc under an anhydrous condition (Reformatsky reaction) thereby obtaining a hydroxy carboxylic acid ester (iii) (reaction formula [1]) in the first place. Then, the obtained hydroxy carboxylic acid ester (iii) is reacted in solvent with a halogen compound (iv) having a polymerizable double bond in the presence of a base, thereby obtaining an unsaturated carboxylic acid ester (v) (reaction formula [2]). Then, the obtained ester (v) is hydrolyzed to obtain an unsaturated carboxylic acid (vi) having a fluorine atom at α-position (reaction formula [3]). At last, the obtained unsaturated carboxylic acid (vi) is reacted in solvent with a halogen compound (vii) in the presence of a base, thereby obtaining a fluorine-containing compound represented by general formula (viii) (reaction formula [4]). In general formula (viii), when W is expressed as W′—O—CR^{d}R^{e}, general formula (viii) represents one mode of general formula (1).

It suffices that the solvent used in the method of the reaction of [1], [2] or [4] is not involved in the reaction in the reaction condition. Aliphatic hydrocarbons such as pentane, hexane and heptane; aromatic hydrocarbons such as benzene, toluene and xylene; nitriles such as acetonitrile, propionitrile, phenylacetonitrile, isobutyronitrile, and benzonitrile; acid amides such as dimethylformamide, dimethylacetamide, methylformamide, formamide, and hexamethylphosphoric triamide; lower ethers such as tetrahydrofuran, 1,2-dimethoxyethane, 1,4-dioxane, diethyl ether, 1,2-epoxyethane, 1,4-dioxane, dibutyl ether, tert-butyl methyl ether, and substituted tetrahydrofurans, etc. are used. Dimethylformamide and tetrahydrofuran are preferable. These solvents can also be used in combination. The amount of the solvent is about 1-100 parts by weight, preferably 1-10 parts by weight, relative to one part by weight of the starting material. It is preferable to remove water as much as possible from the solvent to be used in the reaction of [1]. More preferably, the water content of the solvent is 50 ppm or less.

It is also preferable to remove water as much as possible from the solvent to be used in the reaction of [2] or [4]. It is, however, not necessary to completely remove water. The water close to that generally contained in an industrially available solvent is not particularly problematic in conducting the present production method. Therefore, it can be used directly without removing water.

It is preferable to use the zinc used in the method of the reaction of [1] by activating it by a known method. For example, there are a method to obtain a metallic zinc by reducing a zinc salt, such as zinc chloride, with potassium, magnesium, lithium or the like; an activation method by treating metallic zinc with hydrochloric acid; a method for activating zinc by treating metallic zinc with a copper salt or silver salt in acetic acid to convert it into an alloy with copper or silver; a method for activating zinc by ultrasonic waves; a method for activating zinc by mixing zinc with chlorotrimethylsilane in ether; and a method for activating zinc by bringing zinc into contact with chlorotrimethylsilane and a copper compound in an aprotic organic solvent.

Zinc may have any form, such as powder, granule, aggregate, porous form, cutting scrap, or filament. The reaction temperature of the reaction [1] is about −78 to 120° C. Although the reaction time varies depending on the reaction agents, it is convenient in general to conduct that for about 10 minutes to 20 hours. It suffices that the reaction pressure is around ordinary pressure. The conditions of analogous reactions using metallic zinc publicly known to a person skilled in the art can be applied to other reaction conditions.

As the base in the reactions of [2] and [4], it is possible to cite organic bases such as trimethylamine, triethylamine, diisopropylethylamine, tri-n-propylamine, tri-n-butylamine, dimethyllaurylamine, dimethylaminopyridine, N,N-dimethylaniline, dimethylbenzylamine, 1,8-diazabicyclo(5,4,0)undec-7-ene, 1,4-diazabicyclo(2,2,2)octane, pyridine, 2,4,6-trimethylpyridine, pyrimidine, pyridazine, 3,5-lutidine, 2,6-lutidine, 2,4-lutidine, 2,5-lutidine, 3,4-lutidine, etc. Of these, particularly triethylamine, diisopropylethylamine, dimethylaminopyridine, 1,8-diazabicyclo(5,4,0)undec-7-ene, pyridine, and 2,6-lutidine are preferable.

It suffices that the amount of the base used in the reaction of [2] or [4] is 1 mol or greater relative to 1 mol of the substrate. Generally, 1-10 mols is preferable, and particularly 1-5 mols is more preferable.

In the method of the reaction of [2] or [4], the reaction temperature is about −78 to 120° C. Although the reaction time varies depending on the reaction reagents, it is convenient to conduct that generally for about 10 minutes to 20 hours. The reaction pressure may be around ordinary pressure. Conditions known to a person skilled in the art can be applied to other reaction conditions.

The reaction of [3] is conducted by hydrolyzing that with water in the presence of the above-mentioned basic substance or an inorganic basic substance such as sodium hydroxide, potassium hydroxide, sodium carbonate, calcium hydroxide, etc. It is possible to conduct a purification operation, such as washing, separation of solvent, etc., and drying, in an interval of each reaction step of [1] to [4]. Furthermore, in case that a halogen-containing carboxylic acid ester having a heat-labile protecting group (that is, in case where R^{f}═R² in general formula (i)) is available, it is possible to obtain the target fluorine-containing compound represented by general formula (viii) by conducting the reaction formula [1] and the reaction formula [2].

<Other Copolymerizable Monomers>

The fluorine-containing polymer relating to the water repellent additive of the present invention is one obtained by homopolymerization of the fluorine-containing compound (monomer) or by its copolymerization with “another polymerizable monomer” as will be mentioned below. In the polymerization reaction, a skeleton of the fluorine-containing polymer is formed on the basis of a C—C double bond possessed by a double bond-containing group of the monomer, but the rest of the structure does not change in the polymerization reaction.

For concrete example, a monomer (which may sometimes be referred to as “another polymerizable monomer”) that is copolymerizable with the fluorine-containing compound (monomer) obtained by the above-mentioned method is preferably one obtained by copolymerizing the fluorine-containing polymer at least represented by general formula (1) with one or more kinds of monomers selected from the group consisting of maleic anhydride, acrylic acid esters, fluorine-containing acrylic acid esters, methacrylic acid esters, fluorine-containing methacrylic acid esters, styrene compounds, fluorine-containing styrene compounds, vinyl ethers, fluorine-containing vinyl ethers, allyl ethers, fluorine-containing allyl ethers, olefins, fluorine-containing olefins, norbornene compounds, fluorine-containing norbornene compounds, sulfur dioxide, vinyl silanes, vinyl sulfonic acid, and vinyl sulfonic acid esters.

The above-mentioned copolymerizable acrylic acid esters or methacrylic acid esters can be used without a particular limitation on the ester side chain. As publicly known compounds are shown as examples, it is possible to use acrylic acid or methacrylic acid alkyl esters such as methyl acrylate, methyl methacrylate, ethyl acrylate, ethyl methacrylate, n-propyl acrylate, n-propyl methacrylate, isopropyl acrylate, isopropyl methacrylate, n-butyl acrylate, n-butyl methacrylate, isobutyl acrylate, isobutyl methacrylate, n-hexyl acrylate, n-hexyl methacrylate, n-octyl acrylate, n-octyl methacrylate, 2-ethylhexyl acrylate, 2-ethylhexyl methacrylate, lauryl acrylate, lauryl methacrylate, 2-hydroxyethyl acrylate, 2-hydroxyethyl methacrylate, 2-hydroxypropyl acrylate and 2-hydroxypropyl methacrylate, acrylates or methacrylates containing ethylene glycol, propylene glycol and tetramethylene glycol group, acrylamide, methacrylamide, N-methylolacrylamide, N-methylolmethacrylamide, diacetoneacrylamide, acrylonitrile, methacrylonitrile, acrylic acid, methacrylic acid or vinyl silane containing alkoxy silane, tert-butyl acrylate, tert-butyl methacrylate, 3-oxocyclohexyl acrylate, 3-oxocyclohexyl methacrylate, adamantyl acrylate, adamantyl methacrylate, methyladamantyl acrylate, methyladamantyl methacrylate, ethyladamantyl acrylate, ethyladamantyl methacrylate, hydroxyadamantyl acrylate, hydroxyadamantyl methacrylate, cyclohexyl acrylate, cyclohexyl methacrylate, tricyclodecanyl acrylate, tricyclodecanyl methacrylate, acrylates, methacrylates, acrylic acid or methacrylic acid having a ring structure such as lactone ring and norbornene ring, etc. Furthermore, it is also possible to cause copolymerization with the above-mentioned acrylate compounds containing a cyano group at α-position or with maleic acid, fumaric acid, maleic anhydride or the like serving as similar compound.

Furthermore, the above-mentioned fluorine-containing acrylic acid ester or fluorine-containing methacrylic acid ester is a monomer in which a fluorine atom or fluorine-atom-containing group is contained in α-position of acrylic acid, or an acrylic acid ester or methacrylic acid ester having at ester moiety a substituent having a fluorine atom. A fluorine-containing compound containing fluorine at both α-position and ester moiety is also preferable. Furthermore, a cyano group may be introduced into α-position. For example, as a monomer having α-position into which a fluorine-containing alkyl group is introduced, there is used a monomer in which a trifluoromethyl group, trifluoroethyl group, nonafluoro-n-butyl group or the like has been provided to α-position of the above-mentioned non-fluorine series acrylic acid ester or methacrylic acid ester.

On the other hand, a monomer having fluorine at its ester moiety is an acrylic acid ester or methacrylic acid ester having a unit where the ester moiety is a perfluoroalkyl group or a fluoroalkyl group serving as a flurine-containing group or a unit having both a cyclic structure and a fluorine atom at α-position, the cyclic structure being a fluorine-containing benzene ring, fluorine-containing cyclopentane ring, fluorine -containing cyclohexane ring or fluorine-containing cycloheptane ring or the like in which substitution with a fluorine atom, trifluoromethyl group, hexafluoroisopropyl hydroxyl group or the like has been made. It is also possible to use an acrylic acid or methacrylic acid ester having a fluorine-containing t-butyl ester group at ester moiety. It is also possible to use monomers in which these fluorine-containing functional groups are used in combination with a fluorine-containing alkyl group of α-position. Of such units, as particularly typical ones are exemplarily shown, it is possible to cite 2,2,2-trifluoroethylacrylate, 2,2,3,3-tetrafluoropropylacrylate, 1,1,1,3,3,3-hexafluoroisopropylacrylate, heptafluoroisopropylacrylate, 1,1-dihydroheptafluoro-n-butylacrylate, 1,1,5-trihydrooctafluoro-n-pentylacrylate, 1,1,2,2-tetrahydrotridecafluoro-n-octylacrylate, 1,1,2,2-tetrahydroheptadecafluoro-n-decylacrylate, 2,2,2-trifluoroethylmethacrylate, 2,2,3,3-tetrafluoropropylmethacrylate, 1,1,1,3,3,3-hexafluoroisopropylmethacrylate, heptafluoroisopropylmethacrylate, 1,1-dihydroheptafluoro-n-butylmethacrylate, 1,1,5-trihydrooctafluoro-n-pentylmethacrylate, 1,1,2,2-tetrahydrotridecafluoro-n-octylmethacrylate, 1,1,2,2-tetrahydroheptadecafluoro-n-decylmethacrylate, perfluorocyclohexylmethylacrylate, perfluorocyclohexylmethylmethacrylate, 6-[3,3,3-trifluoro-2-hydroxy-2-(trifluoromethyl)propyl]bicyclo[2.2.1]heptyl-2-yl acrylate, 6-[3,3,3-trifluoro-2-hydroxy-2-(trifluoromethyl)propyl]bicyclo[2.2.1]heptyl-2-yl 2-(trifluoromethyl)acrylate, 6-[3,3,3-trifluoro-2-hydroxy-2-(trifluoromethyl)propyl]bicyclo[2.2.1]heptyl-2-yl methacrylate, 1,4-bis(1,1,1,3,3,3-hexafluoro-2-hydroxyisopropyl)cyclohexylacrylate, 1,4-bis(1,1,1,3,3,3-hexafluoro-2-hydroxyisopropyl)cyclohexylmethacrylate, 1,4-bis(1,1,1,3,3,3-hexafluoro-2-hydroxyisopropyl)cyclohexyl 2-trifluoromethylacrylate, etc.

Furthermore, as a polymerizable monomer having a hexafluoroisopropyl hydroxyl group, which is usable in the copolymerization, is specifically exemplified, it is possible to cite the following compounds. As a fluorine-containing copolymer containing a repeating unit represented by general formula (1), fluorine-containing copolymers containing repeating units obtained by cleavage of these polymerizable monomers having a hexafluoroisopropyl hydroxyl group are particularly preferable since it is easy to keep a balance between water repellency and developing solution solubility.

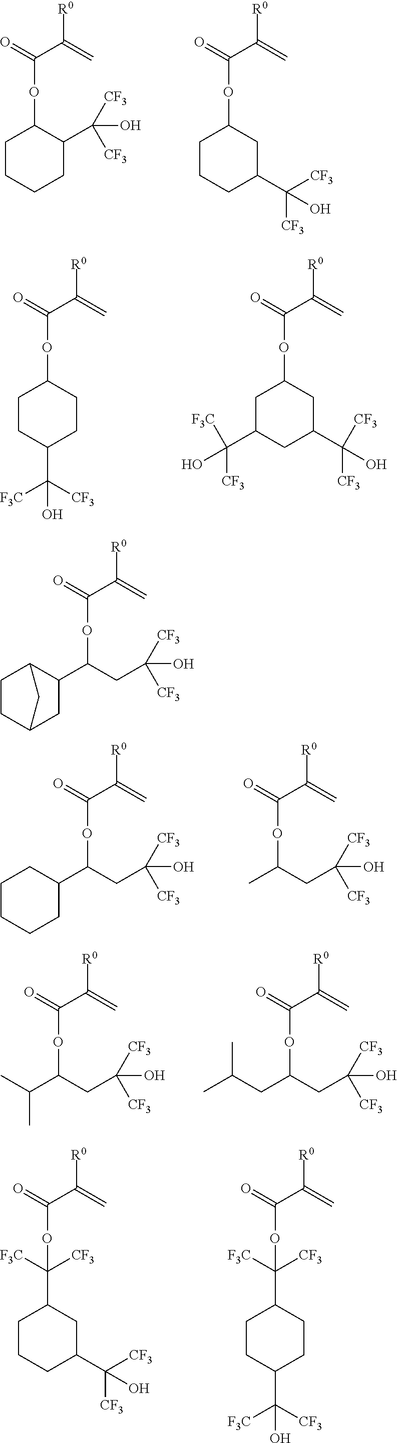

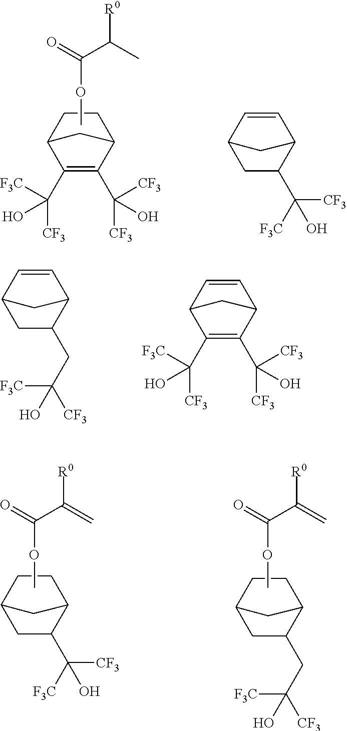

In this case, R⁰ represents a hydrogen atom, methyl group, fluorine atom, or trifluoromethyl group. Furthermore, a hexafluoroisopropyl hydroxyl group may partially or entirely be protected with a protecting group.

Furthermore, as styrene compounds and fluorine-containing styrene compounds usable in the copolymerization, it is possible to cite styrene, fluorinated styrene, hydroxystyrene, etc. More specifically, it is possible to use a styrene in which hydrogen of the aromatic ring has been replaced with fluorine atom or trifluoromethyl group, such as pentafluorostyrene, trifluoromethylstyrene, bistrifluoromethylstyrene, etc., and a styrene in which hydrogen of the aromatic ring has been replaced with hexafluoroisopropyl hydroxyl group or a functional group in which the hydroxyl group has been protected. Furthermore, it is possible to use the above styrene in which halogen, alkyl group or fluorine-containing alkyl group has been bonded to α-position, a perfluorovinyl group-containing styrene, etc.

Furthermore, as vinyl ether, fluorine-containing vinyl ether, allyl ether or fluorine-containing allyl ether usable in the copolymerization, it is possible to use an alkyl vinyl ether or alkyl allyl ether or the like which may have methyl group, ethyl group, propyl group, butyl group or a hydroxyl group such as hydroxyethyl group and hydroxybutyl group. Additionally, it is also possible to use: a cyclic vinyl having a cyclohexyl group, norbornyl group or aromatic ring or having hydrogen or carbonyl bond in its cyclic structure, allyl ether; or a fluorine-containing vinyl ether or fluorine-containing allyl ether in which hydrogens of the above-mentioned functional group have partially or entirely been replaced with fluorine atom.

Additionally, vinyl esters, vinyl silanes, olefins, fluorine-containing olefins, norbornene compounds, fluorine-containing norbornene compounds, and compounds containing other polymerizable unsaturated bonds can also be used in the present invention without particular limitations.

The olefins usable in the copolymerization can be exemplified by ethylene, propylene, isobutene, cyclopentene, cyclohexene, etc., and the fluorine-containing olefins can be exemplified by vinyl fluoride, vinylidene fluoride, trifluoroethylene, chlorotrifluoroethylene, tetrafluoroethylene, hexafluoropropylene, hexafluoroisobutene, etc.

Norbornene compounds and fluorine-containing norbornene compounds, which are usable in the copolymerization, are norbornene monomers having a mononuclear or multinuclear structure. Herein, it is possible to cite norbornene compounds produced by Diels-Alder addition reaction between an unsaturated compound such as fluorine-containing olefin, allyl alcohol, fluorine-containing allyl alcohol, homoallyl alcohol, fluorine-containing homoallyl alcohol, acrylic acid, α-fluoroacrylic acid, α-trifluoromethylacrylic acid, methacrylic acid, all of the acrylic acid esters, methacrylic acid esters, fluorine-containing acrylic acid esters or fluorine-containing methacrylic acid esters mentioned in the present specification, 2-(benzoyloxy)pentafluoropropane, 2-(methoxyethoxymethyloxypentafluoropropene, 2-(tetrahydroxypyranyloxy)pentafluoropropene, 2-(benzoyloxy)trifluoroethylene, 2-(methoxymethyloxy)trifluoroethylene, etc., and cyclopentadiene or cyclohexadiene. They can be exemplified by 3-(5-bicyclo[2.2.1]hepten-2-yl)-1,1,1-trifluoro-2-(trifluoromethyl)-2-propanol, etc.

The fluorine-containing polymer relating to the water repellent additive of the present invention is decomposed by an action of heat or acid and thereby becomes soluble in an alkali developing solution. If it is necessary to further introduce a heat- or acid-labile group into the system, it is easy to introduce a repeating unit having a heat- or acid-labile protecting group as a copolymerization component. As a method for introducing such repeating unit, there is preferably used a method of conducting a copolymerization with another polymerizable monomer having a heat- or acid-labile group.

Furthermore, as another method for obtaining a polymer or resist material having a heat- or acid-lability, it is also possible to conduct a method of later introducing a heat- or acid-labile group into the previously obtained polymer or to mix a heat- or acid-labile compound in the form of a monomer or polymer.

The purpose of using a heat- or acid-labile group is to reveal a positive-type photosensitivity by a heat- or acid-lability and a solubility in an alkali developing solution after exposure with an ultraviolet ray of a wavelength of 300 nm or less, excimer laser, a high-energy ray such as X-ray, or electron beams.

It is possible to use another polymerizable monomer that is copolymerizable and has a heat- or acid-lability usable in the present invention without a particular limitation, as long as it has a group that is released by the effect of photoacid generator, hydrolysis, etc. As it is exemplified, monomers having groups represented by the following general formulas (9) to (11) can preferably be used.

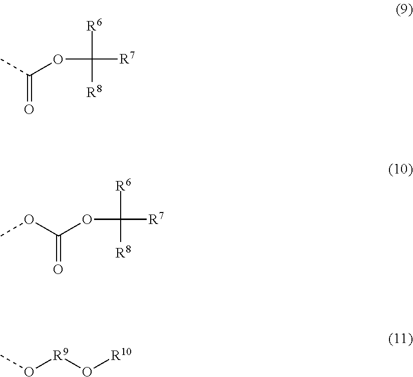

Herein, each of R⁶, R⁷, R⁸, R⁹, and R¹⁰ is independently a C₁₋₂₅ linear, branched, or cyclic alkyl group, and it may partially contain a fluorine atom, oxygen atom, nitrogen atom, sulfur atom or hydroxyl group. Two of R⁴, R⁵ and R⁶ may be bonded to form a ring.

As specific examples of the groups represented by general formulas (9) to (11), they can be exemplified by those shown in the following without a particular limitation.

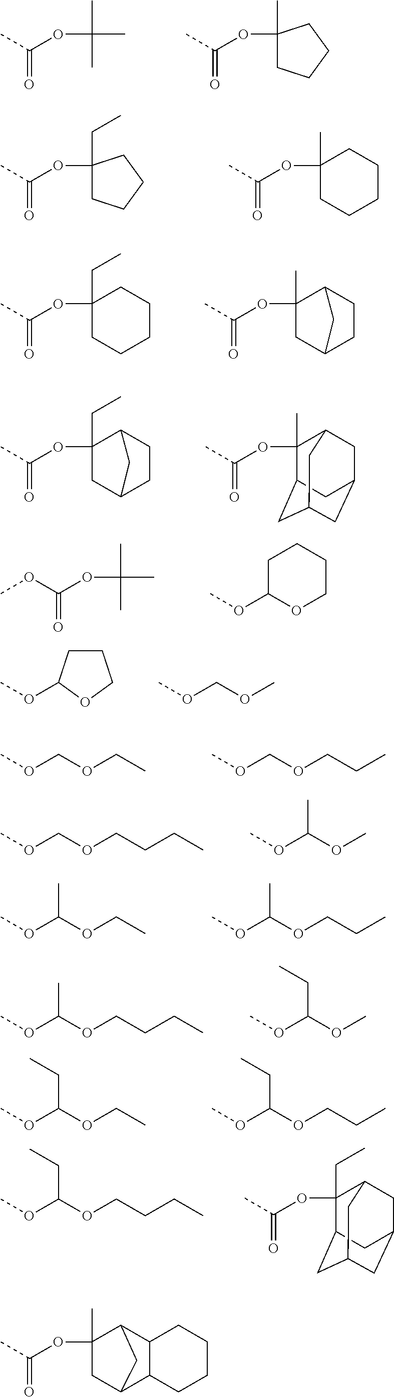

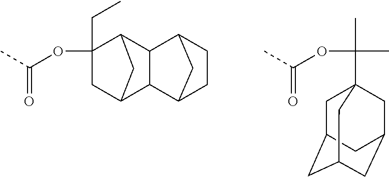

In the production of the fluorine-containing polymer relating to the water repellent additive of the present invention, it is possible to introduce a unit containing a lactone structure for the purpose of improving adhesion with substrate. In introducing such unit, a lactone-containing cyclic polymer is preferably used. Such lactone-containing cyclic polymerizable monomer can be exemplified by a monocyclic lactone such as a group obtained by removing one hydrogen atom from γ-butyrolactone, and a polycyclic lactone such as a group obtained by removing one hydrogen atom from norbornanelactone. By containing a lactone structure in resist, not only adhesion with substrate is improved, but also compatibility with the developing solution can be increased.

Furthermore, the above-mentioned copolymerizable monomer usable in the present invention may be used singly or in combination of at least two types.

The polymer of the present invention may be made up of a repeating unit composed of a plurality of monomers. Its proportion is set without a particular limitation. For example, the range shown in the following is preferably used.

The polymer of the present invention contains a repeating unit represented by general formula (1) and formed from a fluorine-containing polymerizable monomer by 1-100 mol %, more preferably 5-90 mol % while containing a repeating unit having a heat-labile protecting group by 1-100 mol %, more preferably 5-80 mol %, much more preferably 10-60 mol %. In case that the repeating unit represented by general formula (1) and formed from the fluorine-containing polymerizable monomer is less than 1 mol %, an apparent effect obtained by using the monomer of the present invention cannot be expected. Meanwhile, in case that the repeating unit having the heat-labile protecting group is less than 1 mol %, it is not preferable since the change of solubility in an alkali developing solution by exposure is too small.

As the fluorine-containing copolymer containing the repeating unit represented by general formula (1), fluorine-containing copolymers containing a repeating unit represented by general formula (1) exemplified as the most preferable ones mentioned above, and a repeating unit obtained by cleavage of a polymerizable monomer having the above-mentioned hexafluoroisopropyl hydroxyl group are particularly preferable.

The method for polymerizing the fluorine-containing polymer relating to the water repellent additive of the present invention is not particularly limited, as long as it is a method generally used. Radical polymerization, ion polymerization, etc. are preferable. In some cases, it is also possible to use coordination anion polymerization, living anion polymerization, cation polymerization, ring-opening metathesis polymerization, vinylene polymerization, etc.

The radical polymerization may be conducted by a known polymerization method, such as bulk polymerization, solution polymerization, suspension polymerization or emulsion polymerization, in the presence of a radical polymerization initiator or radical initiating source, with a batch-wise, half-continuous or continuous operation.

The radical polymerization initiator is not particularly limited. As the examples, azo compounds, peroxide compounds and redox compounds are cited. In particular, azobisisobutyronitrile, t-butylperoxypivalate, di-t-butylperoxide, i-butyrylperoxide, lauroylperoxide, succinic acid peroxide, dicinnamylperoxide, di-n-propylperoxydicarbonate, t-butylperoxyallyl monocarbonate, benzoyl peroxide, hydrogen peroxide, ammonium persulfate, etc. are preferable.

The reaction vessel used in the polymerization reaction is not particularly limited. Furthermore, a polymerization solvent may be used in the polymerization reaction. As the polymerization solvent, one that does not interfere with the radical polymerization is preferable. Representative ones are ester solvents such as ethyl acetate and n-butyl acetate, ketone solvents such as acetone and methyl isobutyl ketone, hydrocarbon solvents such as toluene and cyclohexane, alcohol solvents such as methanol, isopropyl alcohol and ethylene glycol monomethyl ether, etc. Furthermore, it is also possible to use various solvents such as water, ethers, cyclic ethers, fluorohydrocarbons, and aromatics. These solvents can be used singly or in a mixture of at least two types. Furthermore, it may be accompanied in use with a molecular weight adjusting agent such as mercaptan. The reaction temperature of the copolymerization reaction is suitably changed, depending on the radical polymerization initiator or radical polymerization initiating source. Normally, 20-200° C. is preferable. In particular, 30-140° C. is preferable.

On the other hand, in ring-opening metathesis polymerization, a transition metal catalyst of Groups 4-7 can be used in the presence of a cocatalyst, and a publicly known method can be used in the presence of a solvent.

The polymerization catalyst is not particularly limited. As the examples, Ti series, V series, Mo series and W series catalysts are cited. In particular, titanium (IV) chloride, vanadium (IV) chloride, vanadium trisacetylacetonato, vanadium bisacetylacetonatodichloride, molybdenum (VI) chloride, tungsten (VI) chloride, etc. are preferable. The amount of the catalyst is from 10 mol % to 0.001 mol %, preferably 1 mol % to 0.01 mol %, relative to the monomer used.

As the cocatalyst, alkylaluminum, alkyltin, etc. are cited. In particular, it can be exemplified by aluminum series such as trialkylaluminums such as trimethylaluminum, triethylaluminum, tripropylaluminum, triisopropylaluminum, triisobutylaluminum, tri-2-methylbutylaluminum, tri-3-methylbutylaluminum, tri-2-methylpentylaluminum, tri-3-methylpentylaluminum, tri-4-methylpentylaluminum, tri-2-methylhexylaluminum, tri-3-methylhexylaluminum, and trioctylaluminum; dialkylaluminum halides such as dimethylaluminum chloride, diethylaluminum chloride, diisopropylaluminum chloride, and diisobutylaluminum chloride; monoalkylaluminum halides such as methylaluminum dichloride, ethylaluminum dichloride, ethylaluminum diiodide, propylaluminum dichloride, isopropylaluminum dichloride, butylaluminum dichloride, and isobutylaluminum dichloride; and alkylaluminum sesquichlorides such as methylaluminum sesquichloride, ethylaluminum sesquichloride, propylaluminum sesquichloride; and isobutylaluminum sesquichloride; tetra-n-butyltin, tetraphenyltin, and triphenylchlorotin. The amount of the cocatalyst is by molar ratio a range of 100 equivalents or less, preferably of 30 equivalents or less, relative to the transition metal catalyst.

The polymerization solvent will do, as long as it does not interfere with the polymerization reaction. As representative ones, it can be exemplified by aromatic hydrocarbon series such as benzene, toluene, xylene, chlorobenzene and dichlorobenzene; hydrocarbon series such as hexane, heptane and cyclohexane; and halogenated hydrocarbons such as carbon tetrachloride, chloroform, methylene chloride and 1,2-dichloroethane. These solvents can be used singly or in a mixture of at least two kinds. The reaction temperature is generally preferably −70 to 200° C., particularly preferably −30 to 60° C.

The vinylene polymerization can be conducted in the presence of a cocatalyst by using a transition metal catalyst of Groups 8-10, such as iron, nickel, rhodium, palladium and platinum, or a metal catalyst of Groups 4-6, such as zirconium, titanium, vanadium, chromium, molybdenum, and tungsten. It can be conducted by a publicly known method in the presence of a solvent.

The polymerization catalyst is not particularly limited. As examples, particularly, there are preferable transition metals of Groups 8-10, such as iron(II) chloride, iron(III) chloride, iron(II) bromide, iron(III) bromide, iron(II) acetate, iron(III) acetylacetonato, ferrocene, nickelocene, nickel(II) acetate, nickel bromide, nickel chloride, dichlorohexylnickel acetate, nickel lactate, nickel oxide, nickel tetrafluoroborate, bis(allyl)nickel, bis(cyclopentadienyl)nickel, nickel(II) hexafluoroacetylacetonatotetrahydrate, nickel(II) trifluoroacetylacetonatodihydrate, nickel(II) acetylacetonatotetrahydrate, rhodium(III) chloride, rhodium tris(triphenylphosphine)trichloride, palladium(II) bis(trifluoroacetate), palladium(II) bis(acetylacetonato), palladium(II) 2-ethylhexanoate, palladium(II) bromide, palladium(II) chloride, palladium(II) iodide, palladium(II) oxide, monoacetonitriletris(triphenylphosphine)palladium(II) tretrafluoroborate, tetrakis(acetonitrile)palladium(II) tetrafluoroborate, dichlorobis(acetonitrile)palladium(II), dichlorobis(triphenylphosphine)palladium(II), dichlorobis(benzonitrile)palladium(II), palladium acetylacetonato, palladium bis(acetonitrile)dichloride, palladium bis(dimethylsulfoxide)dichloride and platinum bis(triethylphosphine)hydrobromide, and transition metals of Groups 4-6, such as vanadium(IV) chloride, vanadium trisacetylacetonato, vanadium bisacetylacetonatodichloride, trimethoxy(pentamethylcyclopentadienyl)titanium(IV), bis(cyclopentadienyl)titanium dichloride, and bis(cyclopentadienyl)zirconium dichloride. The amount of the catalyst is from 10 mol % to 0.001 mol %, preferably from 1 mol % to 0.01 mol %, relative to the monomer used.

As the cocatalyst, alkylaluminoxane, alkylaluminum, etc. are cited. In particular, it can be exemplified by methylaluminoxane (MAO), trialkylaluminums such as trimethylaluminum, triethylaluminum, tripropylaluminum, triisopropylaluminum, triisobutylaluminum, tri-2-methylbutylaluminum, tri-3-methylbutylaluminum, tri-2-methylpentylaluminum, tri-3-methylpentylaluminum, tri-4-methylpentylaluminum, tri-2-methylhexylaluminum, tri-3-methylhexylaluminum, and trioctylaluminum; dialkylaluminum halides such as dimethylaluminum chloride, diethylaluminum chloride, diisopropylaluminum chloride, and diisobutylaluminum chloride; monoalkylaluminum halides such as methylaluminum dichloride, ethylaluminum dichloride, ethylaluminum diiodide, propylaluminum dichloride, isopropylaluminum dichloride, butylaluminum dichloride, and isobutylaluminum dichloride; and alkylaluminum sesquichlorides such as methylaluminum sesquichloride, ethylaluminum sesquichloride, propylaluminum sesquichloride, and isobutylaluminum sesquichloride. The amount of the cocatalyst is 50 to 500 equivalents in terms of Al in the case of methylaluminoxane. In the case of other alkylaluminums, it is a range of 100 equivalents or less, preferably of 30 equivalents or less, relative to the transition metal catalyst by molar ratio.

The polymerization solvent will do as long as it does not interfere with the polymerization reaction. As representative ones, it can be exemplified by aromatic hydrocarbon series such as benzene, toluene, xylene, chlorobenzene, and dichlorobenzene; hydrocarbon series such as hexane, heptane, and cyclohexane; halogenated hydrocarbon series such as carbon tetrachloride, chloroform, methylene chloride, and 1,2-dichloroethane; dimethylformamide, N-methylpyrrolidone, and N-cyclohexylpyrrolidone. Furthermore, these solvents may be used singly or in a mixture of at least two kinds. The reaction temperature is generally preferably −70 to 200° C., particularly preferably −40 to 80° C.

As a method of removing an organic solvent or water as a medium from the thus obtained solution or dispersion of the fluorine-containing polymer of the present invention, any of publicly known methods can be used. As it is exemplified, there are methods such as reprecipitation and filtration, or heating distillation under reduced pressure.

As number average molecular weight of the fluorine-containing polymer relating to the water repellent additive of the present invention, generally a range of 1,000 to 100,000, preferably 3,000 to 50,000, is appropriate.

In the use as a water repellent additive, solubility and casting characteristics can be changed depending on the molecular weight. A polymer with a high molecular weight becomes slow in the rate of dissolution in the developing solution. In the case of being low in molecular weight, the rate of dissolution becomes fast. It is controllable by a suitable adjustment.

A water repellent additive according to the present invention can become a water repellent additive-containing resist composition by being mixed with a resist composition, thereby being preferably usable as a chemically amplified positive-type resist material. The mixture ratio of the water repellent additive to a resist composition is 0.1-50 parts by mass, preferably 0.5-10 parts by mass, relative to 100 parts by mass of a base resin. If it is not smaller than 0.1 parts by mass, the receding contact angle formed between the surface of a photoresist film and water is sufficiently improved. Additionally, if it is not larger than 50 parts by mass, the rate of dissolution of the photoresist film in an alkali developing solution is slow so that the height of a formed fine pattern is adequately maintained. The water repellent additive may be mixed with a resist composition as one kind of polymer or may be mixed with the resist composition in such a manner as to mix two or more kinds of compounds.

As a resist composition, one having the following composition is preferably used, for example.

(About the Resist Composition)

(A) Polymer (Base Resin) that becomes soluble in an alkali developing solution by an action of acid

(B) Photoacid Generator

(C) Basic Compound

(D) Solvent

Moreover, (E) Surfactant may be contained therein if necessary.

Hereinafter, explanations will be given for each of the components.

(A) Polymer (Base Resin) That Becomes Soluble in an Alkali Developing Solution by an Action of Acid

As a base resin, a repeating unit having no aromatic substituent is preferably used. It is possible to use a polymer obtained by polymerizing one suitably selected from the above-mentioned “another polymerizable monomer” (i.e., a polymer that does not have the repeating unit represented by general formula (1)). In other words, it is preferably a polymer obtained by polymerizing one kind of monomers selected from the group consisting of maleic anhydride, acrylic acid esters, fluorine-containing acrylic acid esters, methacrylic acid esters, fluorine-containing methacrylic acid esters, styrene compounds, fluorine-containing styrene compounds, vinyl ethers, fluorine-containing vinyl ethers, allyl ethers, fluorine-containing allyl ethers, olefins, fluorine-containing olefins, norbornene compounds, fluorine-containing norbornene compounds, sulfur dioxide, vinyl silanes, vinyl sulfonic acid, and vinyl sulfonic acid esters, or a polymer obtained by copolymerizing two or more kinds of the above-mentioned polymerizable monomers. Concrete examples of each of the polymerizable monomers are as had been discussed as the “another polymerizable monomer”.

In the resist composition used for the present invention, the base resin is insoluble or hard to dissolve in a developing solution (usually, an alkali developing solution) and becomes soluble in the developing solution by acid, so that one having an acid-labile group cleavable by acid is used. As such an acid-labile group, it is possible to cite the following general formulas (9) to (11) for example. In polymerizing the base resin, monomers having those groups are preferably used (R⁶ to R¹⁰ have the same meanings as the foregoing).

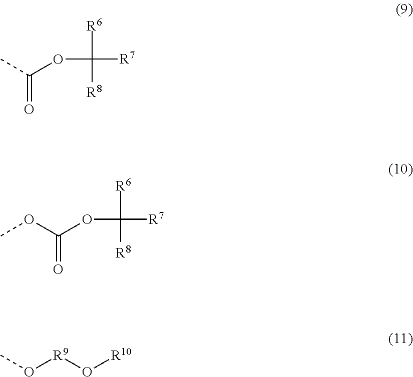

(B) Photoacid Generator

A photoacid generator used for the resist composition relating to the present invention is not particularly limited, and it is possible to use any one selected from those used as an acid generator in a chemically amplified-type resist. As examples of such an acid generator, it is possible to cite onium sulfonates such as iodonium sulfonate and sulfonium sulfonate, sulfonic acid esters, N-imidosulfonate, N-oximesulfonate, o-nitrobenzylsulfonate, trismethanesulfonate of pyrogallol, and the like.

Acids generated from these photoacid generators by an action of light are alkanesulfonic acids, arylsulfonic acids, and partially or entirely fluorinated arylsulfonic acids or alkanesulfonic acids, and the like. Of these, acid generators that generate partially or entirely fluorinated alkanesulfonic acids are effective because these have a sufficient acid strength against protective groups that are difficult in deprotection. As specific examples, it is possible to mention triphenylsulfonium trifluoromethanesulfonate, triphenylsulfonium perfluoro-n-octanesulfonate, and the like.

(C) Basic Compound

It is possible to add a basic compound to the resist composition relating to the present invention. The basic compound has the function of suppressing a diffusion velocity when acid generated by the acid generator diffuses in a resist film. With this, it can be expected to improve the shape of a resist pattern by adjusting diffusion length and to obtain the effect of enhancing the stability at the time of post-exposure delay. If the basic compound is specifically exemplified, it is possible to cite aliphatic amines, aromatic amines, heterocyclic amines, aliphatic polycyclic amines and the like. Of these, secondary or tertiary aliphatic amines are preferable, and alkyl alcohol amines are more preferably employed. Specifically, it is possible to cite trimethylamine, triethylamine, tripropylamine, tributylamine, tripentylamine, trihexylamine, triheptylamine, trioctylamine, trinonylamine, tridecanylamine, tridodecylamine, dimethylamine, diethylamine, dipropylamine, dibutylamine, dipentylamine, dihexylamine, diheptylamine, dioctylamine, dinonylamine, didecanylamine, didodecylamine, dicyclohexylamine, methylamine, ethylamine, propylamine, butylamine, pentylamine, hexylamine, heptylamine, octylamine, nonylamine, decanylamine, dodecylamine, diethanolamine, triethanolamine, diisopropanolamine, triisopropanolamine, dioctanolamine, trioctanolamine, aniline, pyridine, picoline, lutidine, bipyridine, pyrrole, piperidine, piperazine, indole, hexamethylenetetramine and the like. These may be used singly or in combination of two or more kinds. Additionally, the mixture amount thereof is preferably 0.001-2 parts by weight relative to 100 parts by weight of a polymer, more preferably 0.01-1 part by weight relative to 100 parts by weight of the polymer. When the mixture amount is smaller than 0.001 part by weight, the effect of additive is not sufficiently provided. When it exceeds 2 parts by weight, resolution performance or sensitivity is sometimes reduced.

(D) Solvent

A solvent used for a resist composition containing the water repellent additive of the present invention is required only to dissolve each of the mixed components to provide a uniform solution, and may be selected from conventional solvents for resist. Additionally, it is also possible to use two or more kinds of solvents in combination. If the solvent is specifically exemplified, the usable ones are: ketones such as acetone, methyl ethyl ketone, cyclopentanone, cyclohexanone, methyl isobutyl ketone, methyl isopentyl ketone, 2-heptanone and the like; alcohols such as isopropanol, butanol, isobutanol, n-pentanol, isopentanol, tert-pentanol, 4-methyl-2-pentanol, 3-methyl-3-pentanol, 2,3-dimethyl-2-pentanol, n-hexanol, n-heptanol, 2-heptanol, n-octanol, n-decanol, s-amyl alcohol, t-amyl alcohol, isoamyl alcohol, 2-ethyl-1-butanol, lauryl alcohol, hexyl decanol, oleyl alcohol and the like; polyhydric alcohols and derivatives thereof, such as ethylene glycol, diethylene glycol, propylene glycol, dipropylene glycol, ethylene glycol monoacetate, diethylene glycol monoacetate, propylene glycol monoacetate, dipropylene glycol monoacetate, propylene glycol monomethyl ether, propylene glycol monoethyl ether, propylene glycol monopropyl ether, propylene glycol monobutyl ether, propylene glycol monomethyl ether acetate (PGMEA), propylene glycol monomethyl ether (PGME) and the like; esters such as methyl lactate, ethyl lactate (EL), methyl acetate, ethyl acetate, butyl acetate, methyl pyruvate, ethyl pyruvate, methyl methoxypropionate, ethyl ethoxypropionate and the like; aromatic solvents such as toluene, xylene and the like; ethers such as diethyl ether, dioxane, anisole, diisopropyl ether and the like; fluorine-containing solvents such as freon, alternative freon, perfluoro compounds, hexafluoroisopropyl alcohol and the like; solvents weak at high boiling point for the purpose of increasing applicability, such as terpene-based petroleum naphtha solvents, paraffinic solvents and the like.

Of these, propylene glycol monomethyl ether acetate (PGMEA), propylene glycol monomethyl ether (PGME) and ethyl lactate (EL) are particularly preferably adopted.

The amount of the solvent to be mixed into the resist is not particularly limited; however, it is preferably used such that the concentration of a solid content of the resist is 3-25%, more preferably 5-15%. By adjusting the concentration of the solid content of the resist, it becomes possible to adjust the film thickness of a film of the resin to be formed.

(E) Surfactant

In the resist composition of the present invention, a surfactant may be added as necessary. As such a surfactant, any one or two or more kinds of a fluorine-containing surfactant, a silicon-containing surfactant and a surfactant having both fluorine atom and silicon atom may be contained therein.

In immersion lithography, water repellency of a resist film necessary on scanning can be evaluated mainly by receding contact angle. In order to have less defects of a fine pattern formed on the resist, it is preferable to have a receding contact angle of 70° or greater, more preferably 75° or greater.

(Pattern Forming Method)

In the following, there will be explained a pattern forming method in the case of using the present invention in the device production using immersion lithography. The pattern forming method of the present invention is a pattern forming method characterized by involving:

a step of applying a water repellent additive-containing resist composition onto a substrate;

a step of conducting an exposure with a high-energy ray having a wavelength of 300 nm or shorter through a photomask under a condition that a medium is inserted between a projector lens and the substrate, after subjecting the coated substrate to a prebaking; and

a step of carrying out a post-exposure baking of the substrate which had been subjected to the exposure, and then conducting a development by using a developing solution.

Hereinafter, there will be explained each of the steps.

(1) Step of Applying a Water Repellent Additive-Containing Resist Composition onto a Substrate

Firstly, a water repellent additive-containing resist composition solution is applied onto a silicon wafer or a support of a semiconductor production substrate by a spinner or the like. As the substrate, it is also possible to use a substrate formed of metal or glass, in addition to the silicon wafer. Additionally, on the substrate, an organic or inorganic film may be formed. For example, there may be an antireflective film, or an underlayer of multilayer resist. Furthermore, a pattern may be formed thereon.

(2) Step of Inserting an Immersion Medium Between a Projector Lens and a Wafer After Prebaking, and Then Conducting an Exposure with a High-Energy Ray having a Wavelength of 300 nm or Shorter Through a Photomask

Since segregation of the water repellent additive occurs on the surface of the resist film formed by application, a heat treatment (prebaking) is conducted. With this, a resin film in which segregation of the water repellent additive occurs is formed on the resist film. It is possible to suitably set the conditions of this step, depending on the composition of the resist composition and the water repellent additive solution to be used. It is important to conduct the step at a temperature not higher than thermal decomposition temperature of the heat-labile protecting group. That is, temperature of the prebaking is not higher than thermal decomposition temperature of the heat-labile group, and it is conducted at 50-100° C., preferably 60-90° C., for 10-120 seconds, preferably 30-90 seconds.

On the substrate on which the resin film is formed, an immersion medium (which may sometimes be referred to as merely a medium) such as water is disposed. As the immersion medium, it is possible to cite a fluorine-containing solvent, a silicon-containing solvent, a hydrocarbon-containing solvent, a sulfur-containing solvent and the like; however, water is preferably used.

Then, irradiation with a high-energy ray of 300 nm or less is performed through a desired mask pattern. At this time, an exposure light passes through the medium (e.g., water) and the layer in which the water repellent additive causes segregation, and reaches the resist layer. Furthermore, since the resist layer is protected from the medium (e.g., water) by the layer in which the water repellent additive causes segregation, the medium (e.g., water) does not swell the resist layer by immersion, nor does the resist dissolves into the medium (e.g., water).

The wavelength used for exposure is not particularly limited, but a high-energy ray of 300 nm or less is used. It is possible to preferably use KrF excimer laser, ArF excimer laser, F₂ laser, EUV, EB or X-rays. In particular, ArF excimer laser is preferably employed.

(3) Step of Conducting a Development by Using a Developing Solution After a Post-Exposure Baking

Next, the exposed substrate is subjected to a post-exposure baking. By conducting the post-exposure baking at the thermal decomposition temperature of the heat-labile protecting group or higher, the protecting group is released, so that carboxylic acid is exposed to reduce the contact angle at the surface. Concurrently with this, it becomes soluble in the alkali developing solution. A post-exposure baking treatment is conducted at 60-170° C. Then, a development treatment is conducted by using a developing solution, for example, an alkali aqueous solution such as 0.1-10 mass % tetramethylammonium hydroxide aqueous solution. In the development treatment, firstly, the layer in which the water repellent additive causes segregation is fully dissolved, and then the resist film of the exposed portion is dissolved. That is, it is possible to dissolve and remove the layer in which the water repellent additive causes segregation and a portion of the resist layer by a single development treatment, and it is possible to obtain a resist pattern corresponding to a desired mask pattern.

### EXAMPLES

In the following, the present invention is explained in detail by citing examples. The present invention is, however, not limited to the following examples.

### Synthesis Example 1-1

### Method for Producing 2,2-difluoro-3-hydroxypentanoic acid ethyl ester

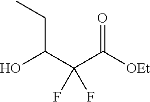

A 500 mL reactor was charged with 24.2 g (370 mmol/1.5 equivalents) of an activated metal zinc and 300 mL of THF (dehydrated), and thereto an ethyl bromodifluoroacetate/THF solution [51.47 g (253.6 mmol/1.0 equivalent) of ethyl bromodifluoroacetate and 80 mL of THF (dehydrated)] was added dropwise. After the dropping, stirring was conducted at room temperature for 20 minutes. Then, a propionaldehyde/THF solution [14.80 g (254.8 mmol/1.0 equivalent) of propionaldehyde and 80 mL of THF (dehydrated)] was added, followed by stirring at room temperature for 30 minutes. Then, water and diisopropyl ether were added to conduct a two-layer separation. The obtained organic layer was washed with diluted hydrochloric acid and water, followed by removing the water content by magnesium sulfate, conducting a filtration, and distilling diisopropyl ether out, thereby obtaining 41.2 g of the target 2,2-difluoro-3-hydroxypentanoic acid ethyl ester. Upon this, yield was 89%.

### Properties of 2,2-difluoro-3-hydroxypentanoic acid ethyl ester

¹H NMR (CDCl₃) d 4.31 (q, J=7.1 Hz, 2H; CH₂—O), 3.89 (m, 1H; CH—OH), 2.50 (br, 1H; OH), 1.71 (m, 1H), 1.52 (m, 1H), 1.32 (t, J=7.1 Hz, 3H; CH₃), 1.02 (t, J=7.3 Hz, 3H; CH₃)

¹⁹F NMR (CDCl₃) d −115.26 (d, J=252 Hz, 1F), −122.95 (d, J=252 Hz, 1F).

### Synthesis Example 1-2

### Method for Producing methacrylic acid 1-ethoxycarbonyl-1,1-difluoro-2-butyl ester

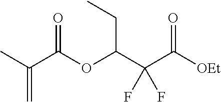

A 300 mL reactor was charged with 18.0 g (98.4 mmol) of 2,2-difluoro-3-hydroxypentanoic acid ethyl ester, 78 g of chloroform, 120 mg of an antioxidant NONFLEX MBP (a product of Seiko Chemical Co., Ltd.), 12.4 g (118.8 mmol/1.2 equivalents) of methacrylic acid chloride, and 15.0 g (148.8 mmol/1.5 equivalents) of triethylamine, followed by stirring at 55° C. for 4 hours. Then, 120 g of water was added, followed by extraction with chloroform one time. The obtained organic layer was washed with diluted hydrochloric acid and water, followed by removing the water content with magnesium sulfate, conducting a filtration, and distilling chloroform out, thereby obtaining 24.7 g of the target methacrylic acid 1-ethoxycarbonyl-1,1-difluoro-2-butyl ester. Upon this, purity was 66%, and yield was 66%.

### Properties of methacrylic acid 1-ethoxycarbonyl-1,1-difluoro-2-butyl ester

¹H NMR (CDCl₃) d 6.14 (s, 1H; methylene), 5.62 (s, 1H; methylene), 5.35 (m, 1H; CH—O), 4.27 (m, 2H; CH₂—O), 1.93 (s, 3H; CH₃), 1.81 (m, 2H; CH₂) 1.28 (t, J=7.2 Hz, 3H; CH₃), 0.95 (t, J=7.6 Hz, 3H; CH₃)

¹⁹F NMR (CDCl₁₃) d −113.63 (d, J=264 Hz, 1F), −119.57 (d, J=264 Hz, 1F).

### Synthesis Example 2

### Method for Producing methacrylic acid 1-hydroxycarbonyl-1,1-difluoro-2-butyl ester

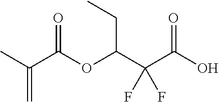

A 2 L reactor was charged with 80.0 g (purity 66%, 208 mmol) of methacrylic acid 1-ethoxycarbonyl-1,1-difluoro-2-butyl ester and 80.0 g of water, followed by cooling down to 0° C., adding dropwise 84.8 g (320 mmol/1.5 equivalents) of 15 wt % sodium hydroxide aqueous solution, and stirring at room temperature for 1 hour. The reaction liquid was washed with 800 g of diisopropyl ether. The obtained aqueous layer was washed with diluted hydrochloric acid, followed by extraction with diisopropyl ether two times, removing the water content by magnesium sulfate, conducting filtration, and distilling diisopropyl ether out, thereby obtaining 15.2 g of the target methacrylic acid 1-hydroxycarbonyl-1,1-difluoro-2-butyl ester. Upon this, purity was 78%, and yield was 27%.

### Properties of methacrylic acid 1-hydroxycarbonyl-1,1-difluoro-2-butyl ester

¹H NMR (CDCl₃) d 7.24 (br, 1H; COOH), 6.16 (s, 1H; methylene), 5.63 (s, 1H; methylene), 5.39 (m, 1H; CH—O), 1.93 (s, 3H; CH₃), 1.85 (m, 2H; CH₂), 0.97 (t, J=7.6 Hz, 3H; CH₃)

¹⁹F NMR (CDCl₃) d −114.24 (d, J=264 Hz, 1F), −119.48 (d, J=264 Hz, 1F).

### Synthesis Example 3

### Method for Producing methacrylic acid 1-(1-methylcyclopentyloxycarbonyl)-1,1-difluoro-2-butyl ester

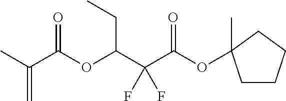

A 2 L reactor was charged under nitrogen with 7.0 g (purity 78%, 25 mmol) of methacrylic acid 1-hydroxycarbonyl-1,1-difluoro-2-butyl ester and 300 mL of THF (dehydrated), followed by cooling down to 0° C., adding 6.5 mL (47 mmol/1.9 equivalents) of triethylamine, and stirring at 0° C. for 10 minutes. Then, furthermore 4.7 g (40.0 mmol/1.6 equivalents) of 1-chloro-1-methylcyclopentane was added, followed by stirring at 0° C. for 20 minutes. To the reaction liquid 500 mL of water was added, followed by extraction two times with diisopropyl ether, removing the water content by magnesium sulfate, conducting a filtration, and distilling diisopropyl ether out, thereby obtaining 6.6 g of the target methacrylic acid 1-(1-methylcyclopentyloxycarbonyl)-1,1-difluoro-2-butyl ester. Upon this, purity was 96%, and yield was 83%.

### Properties of methacrylic acid 1-(1-methylcyclopentyloxycarbonyl)-1,1-difluoro-2-butyl ester

¹H NMR (measurement solvent: deuterated chloroform, standard substance: tetramethylsilane); δ=6.14 (s, 1H; ═CH₂), 5.61 (s, 1H; ═CH₂), 5.35 (m, 1H; CH—O), 2.09 (m, 2H; cyclopentyl moiety), 1.92 (s, 3H; CH₃—C), 1.82 (m, 2H; CH—CH₂CH₃), 1.67 (m, 6H; cyclopentyl moiety), 1.53 (s, 3H; COO—C—CH₃), 0.94 (t, J=7.6 Hz, 3H; CH—CH₂CH₃).

¹⁹F NMR (measurement solvent: deuterated chloroform, standard substance: trichlorofluoromethane); δ=−113.20 (d, J=262 Hz, 1F), −119.65 (d, J=262 Hz, 1F).

### Synthesis Example 4

### Method for Producing methacrylic acid 1-(1-ethylcyclopentyloxycarbonyl-1,1-difluoro-2-butyl ester

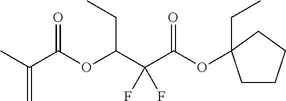

A 2 L reactor was charged under nitrogen with 5.6 g (purity 78%, 20.0 mmol) of methacrylic acid 1-hydroxycarbonyl-1,1-difluoro-2-butyl ester and 240 mL of THF (dehydrated), followed by cooling down to 0° C., adding 5.2 mL (37.6 mmol/1.9 equivalents) of triethylamine, and stirring at 0° C. for 10 minutes. Then, furthermore 14.24 g (3.2 mmol/1.6 equivalents) of 1-chloro-1-ethylcyclopentane was added, followed by stirring at 0° C. for 20 minutes. To the reaction liquid 800 mL of water was added, followed by extraction two times with diisopropyl ether, removing the water content by magnesium sulfate, conducting a filtration, and distilling diisopropyl ether out, thereby obtaining 5.52 g of the target methacrylic acid 1-(1-ethylcyclopentyloxycarbonyl)-1,1-difluoro-2-butyl ester. Upon this, purity was 96%, and yield was 83%.

### Properties of methacrylic acid 1-(1-ethylcyclopentyloxycarbonyl)-1,1-difluoro-2-butyl ester

¹H NMR (measurement solvent: deuterated chloroform, standard substance: tetramethylsilane); δ=6.15 (s, 1H; ═CH₂), 5.61 (s, 1H; ═CH₂), 5.35 (m, 1H; CH—O), 2.08 (m, 2H; cyclopentyl moiety), 2.02 (q, J=7.6 Hz, 2H; COO—C—CH₂CH₃), 1.93 (s, 3H; CH₃—C), 1.82 (m, 2H; CH—CH₂CH₃), 1.62 (m, 6H; cyclopentyl moiety), 0.94 (t, J=7.6 Hz, 3H; COO—C—CH₂CH₃), 0.84 (t, J=7.6 Hz, 3H; CH—CH₂CH₃).

¹⁹F NMR (measurement solvent: deuterated chloroform, standard substance: trichlorofluoromethane); δ=−112.93 (d, J=262 Hz, 1F), −118.80 (d, J=262 Hz, 1F).

### EXAMPLE 1

### Synthesis of Fluorine-Containing Polymer

A fluorine-containing polymer was synthesized by a method described in the following example. Besides, molecular weight (weight average molecular weight Mw) and molecular weight dispersion (the ratio of Mw to number average molecular weight Mn; Mw/Mn) of the polymer were calculated by gel permeation chromatography (GPC, standard substance: polystyrene).

GPC machine: HLC-8320GPC made by Tosoh Corporation

Column used: ALPHA-M column (one) and ALPHA-2500 column (one) made by Tosoh Corporation were used by connecting them in series.

Development solvent: tetrahydrofuran

Detector: refractive index detector

### EXAMPLE 1-1

### Synthesis Example 1 of Fluorine-Containing Polymer Resin

(Fluorine-Containing Polymer (1): MA-PFA-MCP/MA-MIB-HFA=75/25 Copolymerization System)

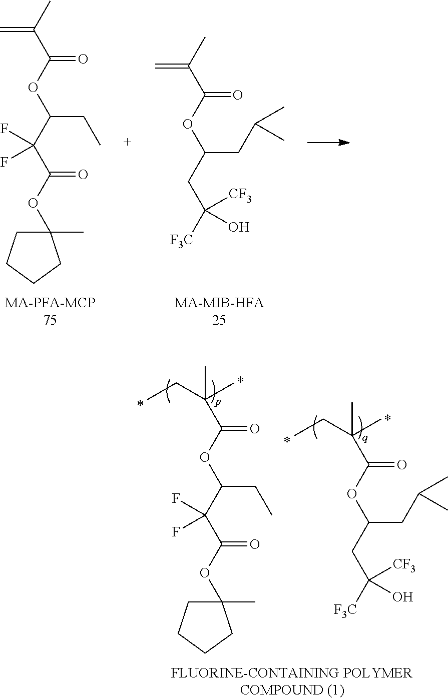

In a glass flask, 1.46 g (4.80 mmol) of MA-PFA-MCP and 0.54 g (1.60 mmol) of MA-MIB-HFA were dissolved in 6.01 g of 2-butanone. To this solution, 0.061 g (0.25 mmol) of a polymerization initiator p-PV (product name t-butylperoxypivalate, made by NOF CORPORATION) was added. With stirring, deaeration was conducted. After introducing nitrogen gas, a reaction was conducted at 60° C. for 20 hours. The solution after the reaction was concentrated. Then, while stirring the concentrated solution, n-heptane (300 g) was added gradually. The obtained precipitate was dried, thereby obtaining 1.61 g of a white-colored solid (a fluorine-containing polymer (1)) (yield 80%). The compositional ratio of the repeating unit was determined in NMR, and the molecular weight was calculated by gel permeation chromatography (GPC, standard substance: polystyrene). The results are shown in Table 1.

### EXAMPLE 1-2

### Synthesis Example 2 of Fluorine-Containing Polymer Resin

(Fluorine-Containing Polymer (2): MA-PFA-MCP/MA-MIB-HFA=50/50 Copolymerization System)

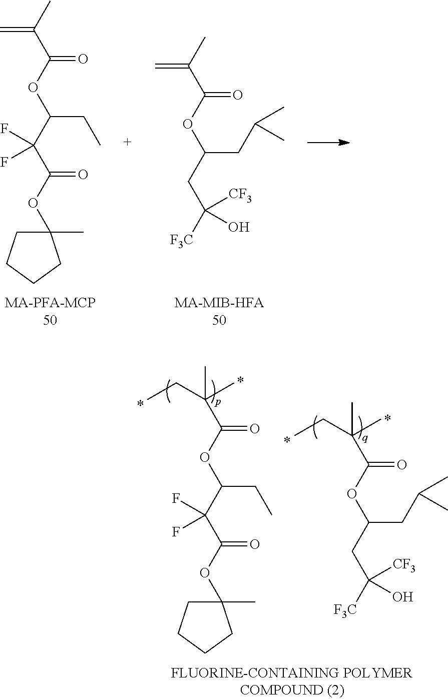

In a glass flask, 0.95 g (3.12 mmol) of MA-PFA-MCP and 1.05 g (3.12 mmol) of MA-MIB-HFA were dissolved in 6.00 g of 2-butanone. To this solution, 0.077 g (0.31 mmol) of a polymerization initiator p-PV (product name t-butylperoxypivalate, made by NOF CORPORATION) was added. With stirring, deaeration was conducted. After introducing nitrogen gas, a reaction was conducted at 60° C. for 20 hours. The solution after the reaction was concentrated. Then, while stirring the concentrated solution, n-heptane (300 g) was added gradually. The obtained precipitate was dried, thereby obtaining 1.72 g of a white-colored solid (a fluorine-containing polymer (2)) (yield 86%). The compositional ratio of the repeating unit was determined in NMR, and the molecular weight was calculated by gel permeation chromatography (GPC, standard substance: polystyrene). The results are shown in Table 1.

### EXAMPLE 1-3

### Synthesis Example 3 of Fluorine-Containing Polymer Resin

(Fluorine-Containing Polymer (3): MA-PFA-MCP/MA-MIB-HFA=25/75 Copolymerization System)

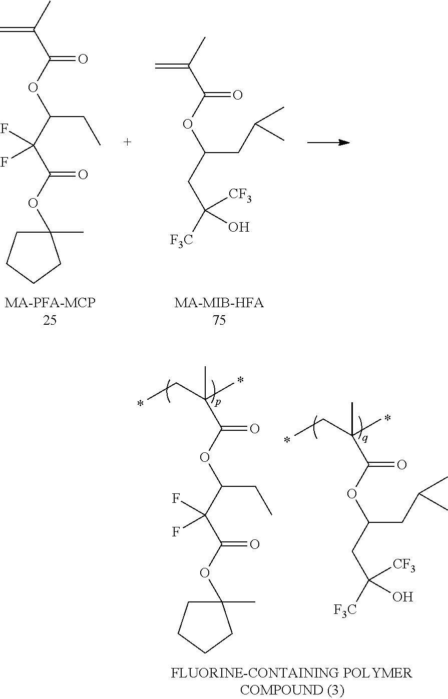

In a glass flask, 0.46 g (1.52 mmol) of MA-PFA-MCP and 1.54 g (4.57 mmol) of MA-MIB-HFA were dissolved in 6.00 g of 2-butanone. To this solution, 0.060 g (0.24 mmol) of a polymerization initiator p-PV (product name t-butylperoxypivalate, made by NOF CORPORATION) was added. With stirring, deaeration was conducted. After introducing nitrogen gas, a reaction was conducted at 60° C. for 20 hours. The solution after the reaction was concentrated. Then, while stirring the concentrated solution, n-heptane (300 g) was added gradually. The obtained precipitate was dried, thereby obtaining 1.75 g of a white-colored solid (a fluorine-containing polymer (3)) (yield 87%). The compositional ratio of the repeating unit was determined in NMR, and the molecular weight was calculated by gel permeation chromatography (GPC, standard substance: polystyrene). The results are shown in Table 1.

### EXAMPLE 1-4

### Synthesis Example 4 of Fluorine-Containing Polymer Resin

(Fluorine-Containing Polymer (4): MA-PFA-ECP/MA-MIB-HFA=50/50 Copolymerization System)

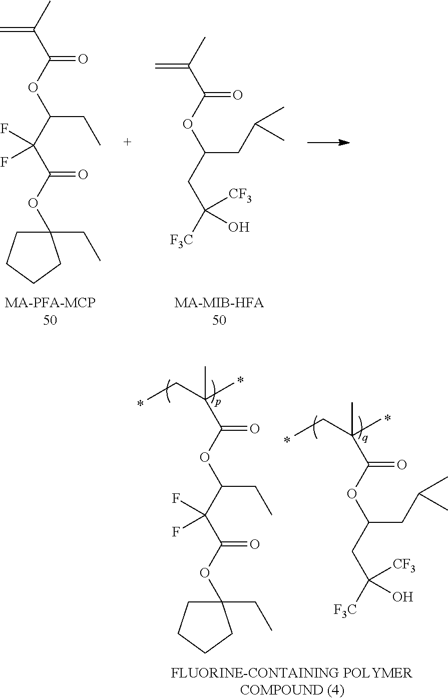

In a glass flask, 0.98 g (3.09 mmol) of MA-PFA-ECP and 1.03 g (3.06 mmol) of MA-MIB-HFA were dissolved in 6.00 g of 2-butanone. To this solution, 0.060 g (0.24 mmol) of a polymerization initiator p-PV (product name t-butylperoxypivalate, made by NOF CORPORATION) was added. With stirring, deaeration was conducted. After introducing nitrogen gas, a reaction was conducted at 60° C. for 20 hours. The solution after the reaction was concentrated. An organic two-layer washing was conducted with n-heptane (20.0 g) and methanol (4.10 g). The solvent was distilled out, thereby obtaining 1.47 g of a white-colored solid (a fluorine-containing polymer (4)) (yield 73%). The compositional ratio of the repeating unit was determined in NMR, and the molecular weight was calculated by gel permeation chromatography (GPC, standard substance: polystyrene). The results are shown in Table 1.

Besides, it was confirmed that the fluorine-containing polymers (1) to (4) are soluble in a weak solvent, 4-methyl-2-pentanol (MIBC).

TABLE 1

| | | | | Molar |
|---|---|---|---|---|
| | | Mw(Mw/ | | compositional |
| Example | Polymer | Mn) | Monomers | ratio |
| Example | Fluorine- | 17,400 | MA-PFA-MCP/ | 68/32 |
| 1-1 | containing | (2.09) | MA-MIB-HFA | (75/25) |
| | polymer (1) | | | |
| Example | Fluorine- | 12,400 | MA-PFA-MCP/ | 42/58 |
| 1-2 | containing | (2.51) | MA-MIB-HFA | (50/50) |
| | polymer (2) | | | |
| Example | Fluorine- | 20,500 | MA-PFA-MCP/ | 23/77 |
| 1-3 | containing | (2.59) | MA-MIB-HFA | (25/75) |
| | polymer (3) | | | |
| Example | Fluorine- | 6,400 | MA-PFA-ECP/ | 36/64 |
| 1-4 | containing | (2.22) | MA-MIB-HFA | (50/50) |
| | polymer (4) | | | |

In Table, the compositional ratio of the preparation is shown in the parenthesis of the column of molar compositional ratio.

### EXAMPLE 2

### Water Repellent Additive Test

In order to study a resin property of the water repellent additive itself, the following experiment was conducted before the addition to the resist composition.

[Preparation of Water Repellent Additive Solution]

The fluorine-containing polymers (1) to (4) synthesized by Example 1 were each dissolved in propylene glycol monomethyl ether acetate (PGMEA). A preparation was conducted such that the solid matter became 5%. Each one was obtained as a homogeneous, transparent, polymer solution (water repellent additive solution).

[Formation of Film of Water Repellent Additive Resin]

Each water repellent additive solution was filtered by a membrane filter (0.2 μm). Then, it was dripped on a silicon wafer previously subjected to oxidation treatment, followed by spinning at a rotation speed of 1,500 rpm by using a spinner and then drying on a hot plate at 60° C. or less for 60 seconds, thereby obtaining a uniform resin film.

[Measurement of Receding Contact Angle]

By using an apparatus CA-X type made by Kyowa Interface Science Co., Ltd., the receding contact angle was measured by an expansion and contraction method.

[Alkali Developing Solution Solubility Test]

The water repellent additive resin film was heated at each temperature for 180 seconds, thereby examining its alkali developing solution solubility. The test was conducted by an immersion at 23° C. for 1 minute by using a 2.38% alkali developing solution (tetramethylammonium hydroxide aqueous solution). The results are shown in Table 2.

TABLE 2

| | | Re- | | | | |
|---|---|---|---|---|---|---|
| | | ceding | Developing solution solubility | | | |
| | | contact | Prior to | | | |
| Exam- | | angle | heat | | | |
| ple | Polymer | (°) | treatment | 90° C. | 120° C. | 130° C. |
| Exam- | Fluorine- | 78 | Insoluble | In- | Soluble | Soluble |
| ple | containing | | | soluble | | |
| 2-1 | polymer | | | | | |
| | (1) | | | | | |
| Exam- | Fluorine- | 78 | Insoluble | In- | Soluble | Soluble |
| ple | containing | | | soluble | | |
| 2-2 | polymer | | | | | |
| | (2) | | | | | |
| Exam- | Fluorine- | 81 | Insoluble | In- | Insoluble | Soluble |
| ple | containing | | | soluble | | |
| 2-3 | polymer | | | | | |
| | (3) | | | | | |
| Exam- | Fluorine- | 74 | Insoluble | Soluble | Soluble | Soluble |
| ple | containing | | | | | |
| 2-4 | polymer | | | | | |
| | (4) | | | | | |

With a higher receding contact angle, fewer droplets remain even if conducting a high-speed scanning exposure. From the results of Table 2, the films of the water repellent additives containing the fluorine-containing polymers (1) to (4) showed high receding contact angles.

Furthermore, the water repellent additives of the present invention prior to the heat treatment were insoluble in the alkali developing solution. However, when conducting a heat treatment at 90-130° C., the protecting group was released, and a good developing solution solubility was shown. Furthermore, the water repellent additive containing the polymer (4) to which MA-PFA-ECP was used exhibited solubility even if the heat treatment temperature was a relatively low temperature.

### EXAMPLE 3-1

### Synthesis of Resist Polymer (Resist Polymer)

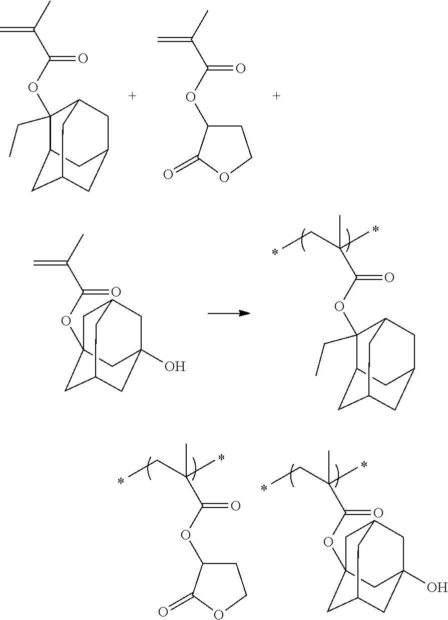

In a glass flask, 13.4 g (54.1 mmol) of ethyl adamantyl methacrylate (MA-EAD), 6.95 g (40.8 mmol) of γ-butyrolactone methacrylate (MA-GBL), and 9.60 g (40.6 mmol) of hydroxyadamantyl methacrylate (MA-HAD) were dissolved in 30.0 g of 2-butanone. To this solution, 0.58 g (2.86 mmol) of n-dodecyl mercaptan (made by Tokyo Chemical Industry Co., Ltd.) and 1.31 g (5.34 mmol) of a polymerization initiator p-PV (product name t-butylperoxypivalate, made by NOF CORPORATION) were added. With stirring, deaeration was conducted. After introducing nitrogen gas, the reaction was conducted at 75° C. for 16 hours. The solution after the reaction was added to 618 g of n-heptane, thereby obtaining a white-colored precipitate. This precipitate was separated by filtration, followed by conducting a drying under reduced pressure at 40° C., thereby obtaining 27.4 g of a white-colored solid (yield 91%). GPC measurement results; Mn=7,400, Mw/Mn=2.13

### EXAMPLE 3-2

### Resist Composition

The resist polymer obtained by Example 3-1 was dissolved in propylene glycol monomethyl ether acetate so as to prepare to have a solid matter content of 5%. Furthermore, triphenylsulfonium nonafluorobutanesulfonate as an acid generator (PAG) to become 5 parts by weight relative to 100 parts by weight of the polymer and isopropanol amine as a base to become 2 parts by weight relative to the same were dissolved, thereby preparing a resist composition.

### EXAMPLE 3-3

### Water Repellent Additive-Containing Resist Composition

The fluorine-containing polymers (1) to (4) prepared by Example 1 were each added to the resist composition prepared by Example 3-2, such that the resin weight ratio of the resist polymer to the fluorine-containing polymer was 90:10, thereby preparing water repellent additive-containing resist solutions (which were named as water repellent additive-containing resist solutions (1) to (4), respectively).

### EXAMPLE 4

### Comparative Example

Each of the water repellent additive-containing resist solutions (1) to (4) prepared by Example 3-3 was filtered by a membrane filter (0.2 μm). Then, it was dripped on a silicon wafer, followed by spinning at a rotation speed of 1,500 rpm using a spinner, and then drying on a hot plate at 60° C. for 60 seconds, thereby obtaining a resist film having a film thickness of 100-150 nm. As a comparative example, a sample of a resist film using the resist composition to which the water repellent additive was not added was provided by the same method.

The obtained resist films were each subjected to pure water immersion test (PAG bleaching evaluation) and exposure resolution test. The results are shown in Table 3.

[Pure Water Immersion Test]

Silicon wafers on which the resin films were formed by the above method were formed were each immersed in 20 mL of pure water for 10 minutes to extract dissolved matters. Then, the extract was measured by ion chromatography to check the existence of dissolved matters. Except one (Comparative Example) with no use of water repellent additive, peaks belonging to the photoacid generator and its decomposed matter were not observed. This indicates that dissolution of the resist components from the resist film to water is suppressed by the formation of the film in which the water repellent additive causes segregation. The results are shown in Table 3. An example having no dissolution of the resist components was represented by “A” as an acceptable one, while an example having dissolution of the resist components was represented by “B” as an unacceptable one.

[Measurement of Receding Contact Angle]

By using an apparatus CA-X type made by Kyowa Interface Science Co., Ltd., the receding contact angle was measured by an expansion and contraction method. The results are shown in Table 3.

[Exposure Test]

Each water repellent additive-containing resist solution was filtered by a membrane filter (0.2 μm). Then, it was dripped on a silicon wafer, followed by spinning at a rotation speed of 1,500 rpm using a spinner. A prebaking was conducted at 60° C. for 60 seconds. Then, using water as medium, an immersion exposure to a 193 nm ultraviolet ray was conducted through a photomask of a 130 nm-size, 1:1 line-and-space (130 nm 1 L/1 S pattern). While the wafer after the exposure was rotated, pure water was dripped thereon for 2 minutes. Then, a post-exposure baking was conducted at 130° C. for 180 seconds, thereby pyrolyzing (releasing) the heat-labile group of the water repellent additive. Then, a development was conducted at 23° C. for 1 minute by using a 2.38% alkali developing solution (tetramethylammonium hydroxide aqueous solution). As a result, with the exception of the resist film of Comparative Example, a high-resolution pattern was obtained from each resist film. There were not found inferiority defect in adhesion to substrate, film-forming inferiority defect, development defect, and etching resistance inferiority defect.

The cross section of the obtained pattern was observed by a scanning electron microscope to observe the pattern shape. The evaluation of the pattern shape at that time is shown in Table 3.

TABLE 3

| | Water | | | |
|---|---|---|---|---|
| | Repellent | | | |
| | Additive- | | Pure | |
| | containing | Receding | Water | |
| | Resist | Contact | Immersion | Pattern |
| Example | Composition | Angle (°) | Test | Shape |
| Example | Water Repellent | 80 | A | Rectangular |
| 4-1 | Additive- | | | Shape |
| | containing | | | |
| | Resist-(1) | | | |
| Example | Water Repellent | 78 | A | Rectangular |
| 4-2 | Additive- | | | Shape |
| | containing | | | |
| | Resist-(2) | | | |
| Example | Water Repellent | 75 | A | Rectangular |
| 4-3 | Additive- | | | Shape |
| | containing | | | |
| | Resist-(3) | | | |
| Example | Water Repellent | 75 | A | Rectangular |
| 4-4 | Additive- | | | Shape |
| | containing | | | |
| | Resist-(4) | | | |
| Com. Ex. | Resist | 50 | B | Swelled |
| | Composition | | | |
| | (Ex. 3-2) | | | |
| | containing No | | | |
| | Water Repellent | | | |
| | Additive | | | |

From the results of Table 3, the pattern shapes of the resin films using the fluorine-containing polymers (1) to (4) as the water repellent additives became rectangular. On the other hand, in a system with no use of water repellent additive, the resist surface swelled, and thereby a good pattern was not obtained.

### INDUSTRIAL APPLICABILITY

The resist composition containing the water repellent additive of the present invention is one in which the water repellent additive causes segregation on the resist surface. With this, a good barrier property against water is exhibited while suppressing dissolution of the photoresist material to water, and therefore it is useful for topcoatless immersion lithography. Additionally, a high water repellency is exhibited so as to allow a high-speed scanning by an immersion exposure apparatus thereby improving productivity. Furthermore, it is possible to greatly enhance solubility in the developing solution by performing the development after heat treatment, so that defects of resist pattern are reduced.

1-11. (canceled)

12. A water repellent additive-containing resist composition comprising:
a resist composition comprising
(A) a polymer that becomes soluble in an alkali developing solution by an action of acid,
(B) a photoacid generator,
(C) a basic compound, and
(D) a solvent; and
a fluorine-containing polymer that has a repeating unit represented by the following general formula (1). 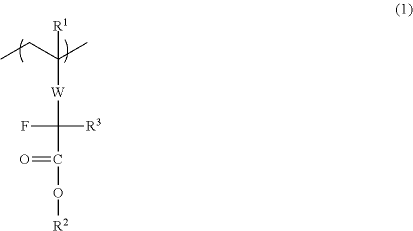
wherein
R¹ represents a hydrogen atom, a fluorine atom, a methyl group or a trifluoromethyl group;
R² represents a heat-labile protecting group;
R³ represents a fluorine atom or a fluorine-containing alkyl group; and W represents a divalent linking group.

13. A water repellent additive-containing resist composition as claimed in claim 12, wherein R³ of the fluorine-containing polymer represents a fluorine atom or a fluorine-containing alkyl group having a carbon number of 1-3.

14. A water repellent additive-containing resist composition as claimed in claim 12, wherein the repeating unit of the fluorine-containing polymer is represented by any one of the following general formulas (1-1) to (1-4). 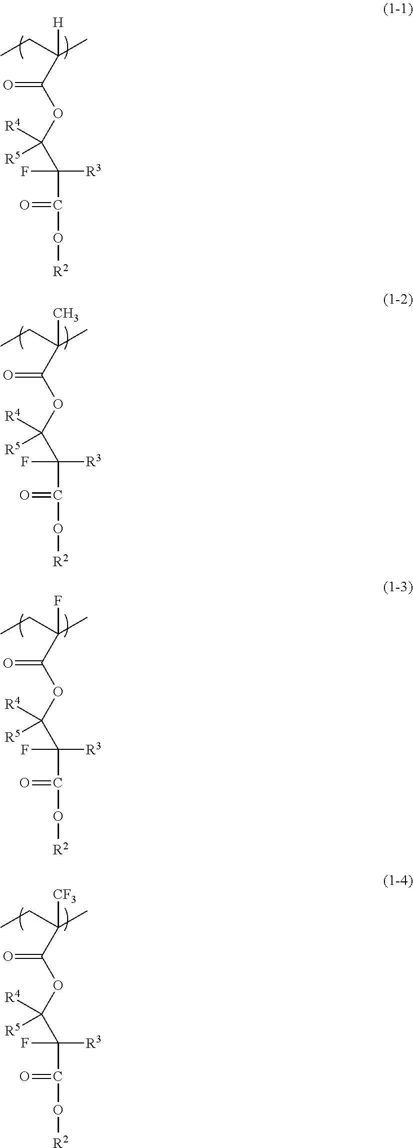
wherein
R² represents a heat-labile protecting group;
R³ represents a fluorine atom or a trifluoromethyl group;
R⁴ represents a hydrogen atom or a linear, branched or cyclic alkyl or fluoroalkyl group;
R⁵ represents a linear, branched or cyclic alkyl or fluoroalkyl group; and
R⁴ and R⁵ may be bonded to each other to form a ring.

15. A water repellent additive-containing resist composition as claimed in claim 12, wherein the fluorine-containing polymer is one in which R² is 1-methylcyclopentyl group or 1-ethylcyclopentyl group, R³ is a fluorine atom, R⁴ is a hydrogen atom, and R⁵ is a lower alkyl group.

16. A pattern forming method comprising the steps of:
(1) a step of applying a resist composition on a substrate;
(2) a step of conducting an exposure with a high-energy ray having a wavelength of 300 nm or shorter through a photomask under a condition that a medium is inserted between a projector lens and the substrate, after subjecting the coated substrate to a prebaking; and
(3) a step of carrying out a post-exposure baking of the substrate which had been subjected to the exposure, and then conducting a development by using a developing solution,
wherein the resist composition is a water repellent additive-containing resist composition comprising
(A) a polymer that becomes soluble in an alkali developing solution by an action of acid,
(B) a photoacid generator,
(C) a basic compound, and
(D) a solvent; and
wherein the water repellent additive-containing resist composition further comprises a fluorine-containing polymer that has a repeating unit represented by the following general formula (1). 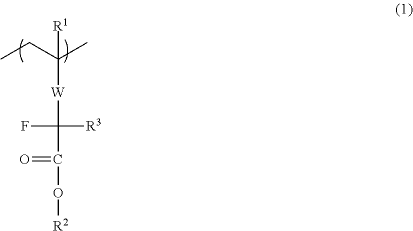
wherein
R¹ represents a hydrogen atom, a fluorine atom, a methyl group or a trifluoromethyl group;
R² represents a heat-labile protecting group;
R³ represents a fluorine atom or a fluorine-containing alkyl group; and
W represents a divalent linking group.

17. A pattern forming method as claimed in claim 16, wherein R³ of the fluorine-containing polymer represents a fluorine atom or a fluorine-containing alkyl group having a carbon number of 1-3.

18. A pattern forming method as claimed in claim 17, wherein the repeating unit of the fluorine-containing polymer is represented by any one of the following general formulas (1-1) to (1-4). 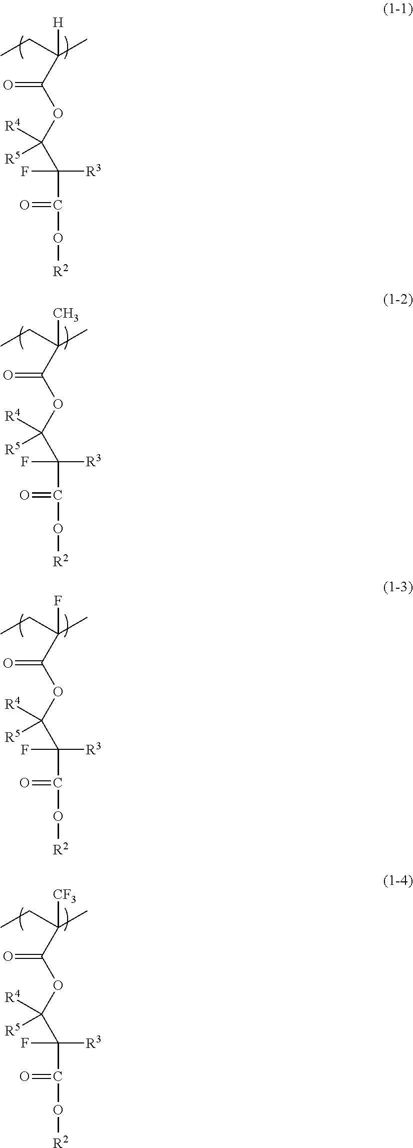
wherein
R² represents a heat-labile protecting group;
R³ represents a fluorine atom or a trifluoromethyl group;
R⁴ represents a hydrogen atom or a linear, branched or cyclic alkyl or fluoroalkyl group;
R⁵ represents a linear, branched or cyclic alkyl or fluoroalkyl group; and
R⁴ and R⁵ may be bonded to each other to form a ring.

19. A pattern forming method as claimed in claim 16, wherein the fluorine-containing polymer is one in which R² is 1-methylcyclopentyl group or 1-ethylcyclopentyl group, R³ is a fluorine atom, R⁴ is a hydrogen atom, and R⁵ is a lower alkyl group.

20. A pattern forming method as claimed in claim 16, wherein the post exposure baking treatment before the development is conducted at 60° C. to 170° C.

21. A pattern forming method as claimed in claim 16, wherein a high-energy ray having a wavelength within a range of from 180 to 300 nm is used as an exposure light source.

22. A water repellent additive used by being added to a resist composition, comprising:
a fluorine-containing polymer that has a repeating unit represented by the following general formula (1) 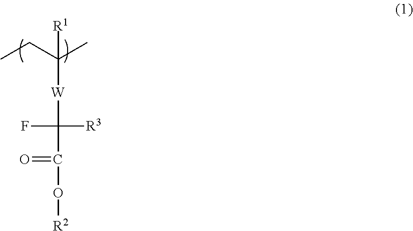
wherein
R¹ represents a hydrogen atom, a fluorine atom, a methyl group or a trifluoromethyl group;
R² represents a heat-labile protecting group;
R³ represents a fluorine atom or a fluorine-containing alkyl group; and
W represents a divalent linking group
wherein the water repellent additive is used as a water repellent additive for immersion resist.
